(19) United States
(12) Patent Application Publication
(10) Pub. No.: US 2015/0344627 A1
(43) Pub. Date: Dec. 3, 2015

(54) LOW MODULUS NEGATIVE TONE, AQUEOUS DEVELOPABLE PHOTORESIST

(71) Applicant: Designer Molecules, Inc., San Diego, CA (US)

(72) Inventor: Farhad G Mizori, San Diego, CA (US)

(21) Appl. No.: 14/646,380

(22) PCT Filed: Nov. 20, 2013
(86) PCT No.: PCT/US2013/071103

§ 371 Date: May 20, 2015

Related U.S. Application Data
(60) Provisional application No. 61/728,651, filed on Nov. 20, 2012.

(51) Int. Cl. C08G 73/10; H01L 21/02; H01L 23/29; H01L 23/31; G03F 7/32; G03F 7/16

(52) U.S. Cl. CPC C08G 73/1082; G03F 7/32; G03F 7/16; H01L 23/293; H01L 23/3171; H01L 21/02118; H01L 21/02282

(57) ABSTRACT

Hydrophobic, low modulus, photoimagable, functionalized polyimides have been discovered that can be developed using aqueous solutions. In particular, compositions containing the functionalized polyimides of the current invention can be used in the photolithography step for the passivation layer on a silicon wafer to reduce stress in thin wafers, or as a low modulus hydrophobic solder mask. These materials can serve as protective layers in other applications in which a thin, flexible, and hydrophobic polymer is required.

### CROSS REFERENCE TO RELATED APPLICATIONS

This application claims the benefit of priority under 35 USC §119 of U.S. Provisional Application Ser. No. 61/728,651 filed Nov. 20, 2012, the entire disclosure of which is incorporated herein by reference.

### FIELD OF THE INVENTION

The present invention relates to hydrophobic, low modulus, photoimagable, functionalized polyimides that can be developed using aqueous solutions. In particular the current invention can be used in the photolithography step for the passivation layer on a silicon wafer to reduce stress in thin wafers, or as a low modulus hydrophobic solder mask. Furthermore, in applications in which a thin, flexible polymeric protective coating is required.

### BACKGROUND OF THE INVENTION

Polyimides have some excellent properties that make them very useful for a variety of high performance applications. These materials are known to possess very high thermal stability along with toughness, and resistance to chemicals and aqueous environments. Polyimides are also known for having very low dielectric constants that make them ideal to use in the electronics and microelectronics applications.

In the field of photolithography and photoresists, polyimides are used very frequently, and in fact most wafer passivation uses some sort of photocurable polyimide film. Polyimide passivation layers are typically 4-6 microns in thickness, and protect the delicate thin films of metals and oxides on the chip surface from damage during handling and from induced stress after encapsulation in plastic molding compound. Patterning is simple and straightforward. Because of the low defect density and robust plasma etch resistance inherent in polyimide films, a single mask process can be implemented, which permits the polyimide layer to function both as a stress buffer and as a dry etch mask for an underlying silicon nitride layer. In addition, polyimide layers have been frequently used for flip-chip bonding applications, including both C-4 and dual-layer bond pad redistribution (BPR) applications. Polyimide layers can be patterned to form the structural components in microelectromechanical systems (MEMS).

Polyimides may also serve as an interlayer dielectric in both semiconductors and thin film multichip modules (MCM-D's). The low dielectric constant, low stress, high modulus, and the inherent ductility of polyimide film make them well suited for these multiple layer applications. Other uses for polyimides include alignment and/or dielectric layers for displays, and as a structural layer in micro machining applications. In lithium-ion battery technology, polyimide films can be used as protective layers for PTC thermistor (positive temperature coefficient) controllers.

In the fabrication of microelectronic devices, polyimides are typically applied as a solution of the corresponding polyamic acid precursors onto a substrate, and then thermally cured into a smooth, rigid, intractable polymeric film or structural layer. The film can be patterned using a lithographic (photographic) process in conjunction with liquid photoresists. Typically, polyimides are formed in situ through cyclodehydration of the polyamic acid precursors. This imidization step also requires the evaporation of high boiling, polar aprotic solvents, which can be difficult to drive away as the polyimide is formed. This step is sometimes referred to as the “hard bake” step in the process, because the required temperature is typically >300° C. for several hours.

Existing polyimide passivation materials generate a high degree of stress on the wafer. This is known to cause delamination of the passivation material. Moreover, as silicon wafers have become thinner, it has been found that the polyimides used for passivation layers tend to warp the wafer upon thermal cure, resulting in a concave or convex wafer surface. This phenomenon creates a variety of problems for the semiconductor fabrication and packaging industry.

Conventional polyimide passivation materials are generally hydrophilic and usually require tedious multi-step processes to form the vias required for electrical interconnects. For example, polyimide materials have been used as interlayer dielectric materials in microelectronic devices such as integrated circuits (IC's) because they have a dielectric constant that is lower than that of silicon dioxide. Also, such polyimide materials can serve as planarization layers for IC's as they are generally applied in a liquid form, allowed to level, and subsequently cured. However, polyimide materials readily absorb moisture even after curing and this absorption can result in device failure. In addition, polyimides are generally not easily patterned as is often required in the manufacture of IC's and other microelectronic devices.

Accordingly, there is a need for hydrophobic, low modulus polyimides that are compatible with very thin silicon wafers, i.e., polyimide passivation layers that will not warp thin silicon wafers.

Furthermore, the need exists for polyimide films that can be developed easily in the photolithography step. Generally, photoresists are classified as two types: negative and positive tone. A “positive resist” is a type of photoresist in which the portion of the photoresist that is exposed to light becomes soluble to the photoresist developer. The portion of the photoresist that is unexposed remains insoluble to the photoresist developer. A “negative resist” is a type of photoresist in which the portion of the photoresist that is exposed to light becomes insoluble to the photoresist developer. The unexposed portion of the photoresist is dissolved by the photoresist developer.

Negative tone photoresists are far more widely used in the microelectronics industry. This is due to the fact that negative tone photoresists are much less expensive, they have superior adhesion to silicon, and they have much better chemical resistance. One of the major disadvantages to using negative tone photoresists is that they are usually developed with organic solvents, and most users of these materials would like the option of using aqueous solutions to develop their photoresists. Thus, polyimide films that can be developed easily would be advantageous for photolithography applications.

### BRIEF DESCRIPTION OF THE DRAWINGS

FIG. 1-3 show a close-up view of a thin coating of the photoimageable polyimide on the surface of a silicon wafer. A photomask was used in the UV curing step and the film was developed using 2.5% TMAH solution. The holes and lines correspond to opaque areas of the photomask (impenetrable by UV light, un-cured soluble regions), while the continuous film in which the holes and lines are embedded correspond to transparent areas of the photomask (UV light-penetrable, cured insoluble regions).

FIG. 1 is a close-up view of a photoimaged and developed film with 3 mil holes (76.2 μm) and 10 mil spacing (254 μm).

FIG. 2 is a close-up view of a photoimaged and developed film with 6 mil holes (152.4 μm) and 20 mil spacing (508 μm).

FIG. 3 is a close-up view of a photoimaged and developed film with 4 mil lines (101.6 μm) and 4 mil spacing (101.6 μm).

FIG. 4 is Dektak Profilometer scan of the photoimaged and developed lines corresponding to FIG. 3. The scan shows a film thickness of approximately 6.5 μm; line width of approximately 100 μm, and clean well developed channels all the way down to the silicon surface.

FIG. 5 is a TGA trace of the UV-cured thick film cast from a toluene solution. Once cured the film shows very high thermal stability up to 350° C. The small amount of weight loss is due to residual toluene trapped in the thick film.

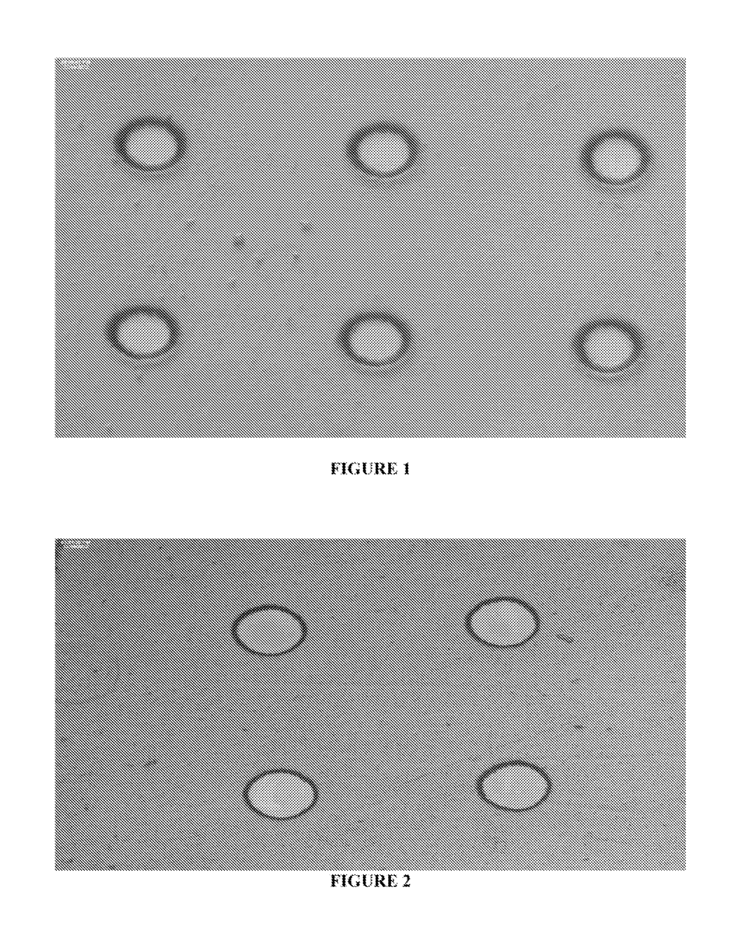

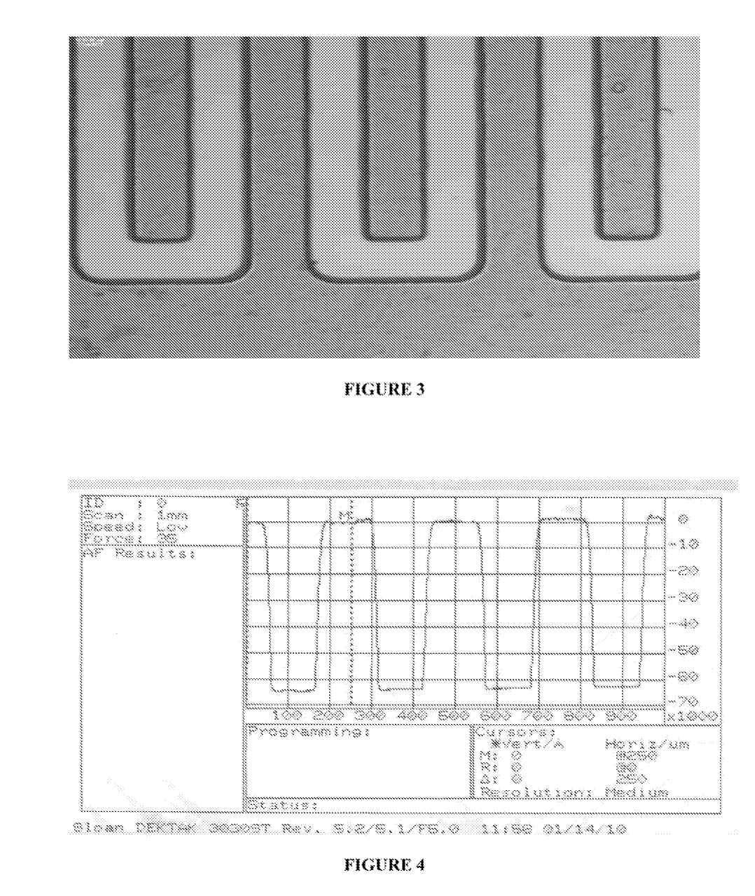

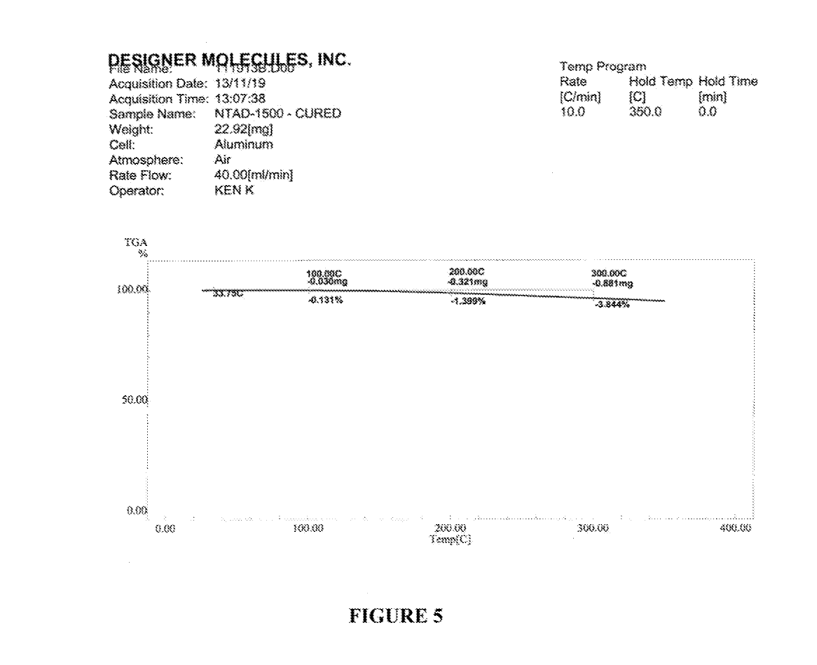

### SUMMARY OF THE INVENTION

According to one embodiment of the invention, a device is provided, comprising a semiconductor wafer, wafer level package, MEMS, PTC protective layer, circuit board, or glass, and a passivation layer disposed on the surface of the wafer. According to some embodiments, the passivation layer is includes a hydrophobic, low modulus polyimide polymer, which is functionalized with photocurable end groups such as acrylate, methacrylate, maleimide, vinyl ether, itaconate, maleate, fumarate, acrylamide, methacrylamide or the like. In some embodiments of the invention the polyimide backbone is pre-imidized or partially imidized to obtain a material that is soluble in common organic solvents such as toluene. This eliminates the need for high boiling polar aprotic solvents as a means for applying the coating to the wafer, and eliminates the need for very high temperature to process the material.

In some aspects, wherein the polyimide coating forms a film after cure that has a modulus of less than 2000 MPa at 25° C. In other embodiments, the modulus is less than 1000 MPa at 25° C. In still further embodiments, the modulus is less than 500 MPa at 25° C.

In another embodiment of the invention, the photoimagable polyimide coating is applied and after the photolithography step, a pattern is developed followed by the excess removal or development stage. The excess polyimide can be developed using organic solvents or aqueous solvent systems.

In yet another embodiment of the invention the compounds of the invention are used in the patterning and etching of a number of substrates, including, but not limited to printed circuit boards, specialty photonics materials, microelectromechanical systems (MEMS), glass, and other micropatterning tasks.

The invention also provides methods of fabricating the device comprising depositing a layer of the functionalized polyimide on the surface of the semiconductor wafer; and curing the functionalized polyimide to thereby form a polyimide passivation layer on the surface of the semiconductor wafer; and developing the uncured functionalized polyimide using an aqueous developing solution, thereby forming a pattern on the surface of the semiconductor wafer. In some aspects, a concentrated solution is made comprising the functionalized polyimide, UV initiators, coupling agents, inhibitors, adhesion promoters, and solvent; and spin coating the solution onto a semiconductor wafer or other substrate.

According to some embodiments of the invention a functionalized polyimide is selected from the group consisting of structural formulae I-VII:

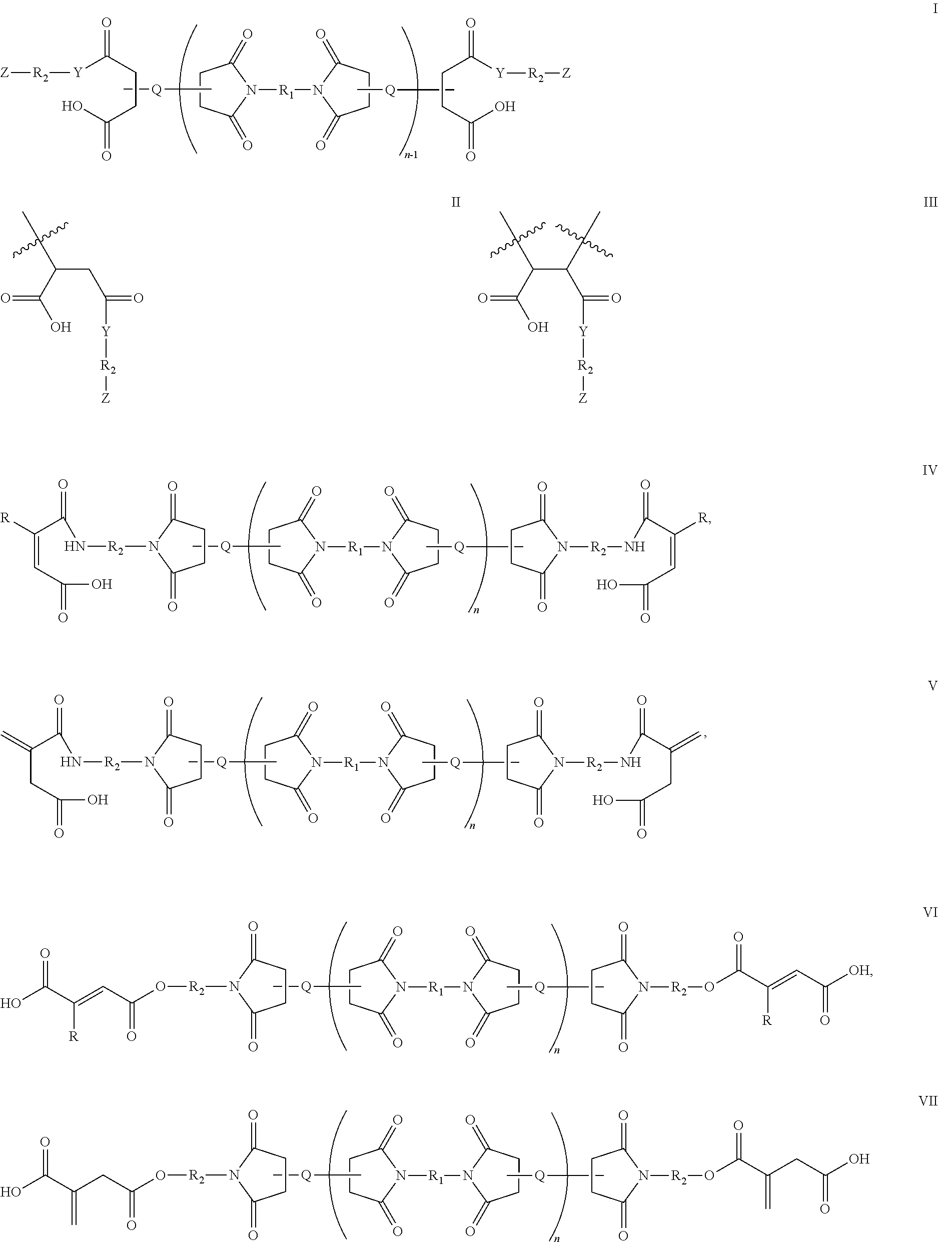

where, each R₁, R₂, and Q is independently selected from the group consisting of substituted or unsubstituted aliphatic, alkenyl, aromatic, heteroaromatic and siloxane moieties, Y is a heteroatom such as oxygen, sulfur or nitrogen, Z is a polymerizable moiety, n is an integer having the value between 1 to about 10, and the symbol “ [symbol] ” depicts schematically a macromolecular chain to which the structure II or III is covalently attached.

The polymerizable moiety can be, for example, a cationic polymerizable moiety, an anionic polymerizable moiety, a ring-opening polymerizable moiety, and a free-radical polymerizable moiety. In certain aspects, the polymerizable moiety is selected from the group consisting of an acrylate, a methacrylate, a vinyl ether, a vinyl ester, an epoxy, an oxetane, a maleimides, a citraconimide, a itaconates, or a maleate.

In certain aspect, each R₁, R₂ and Q is independently selected from a group consisting of: a substituted or an unsubstituted linear, branched, cyclic, aliphatic and alkenyl moieties having between 2 and 500 carbon atoms; and a substituted or unsubstituted aromatic or heteroaromatic moieties having between 6 and 20 carbon atoms. In other embodiments, at least one R₁ or R₂ is a 36-carbon atom moiety.

Included in the functionalized polyimide of the invention are those that have an acid equivalent weight between 300 and 2000 g per equivalent.

Exemplary functionalized polyimides of the invention include:

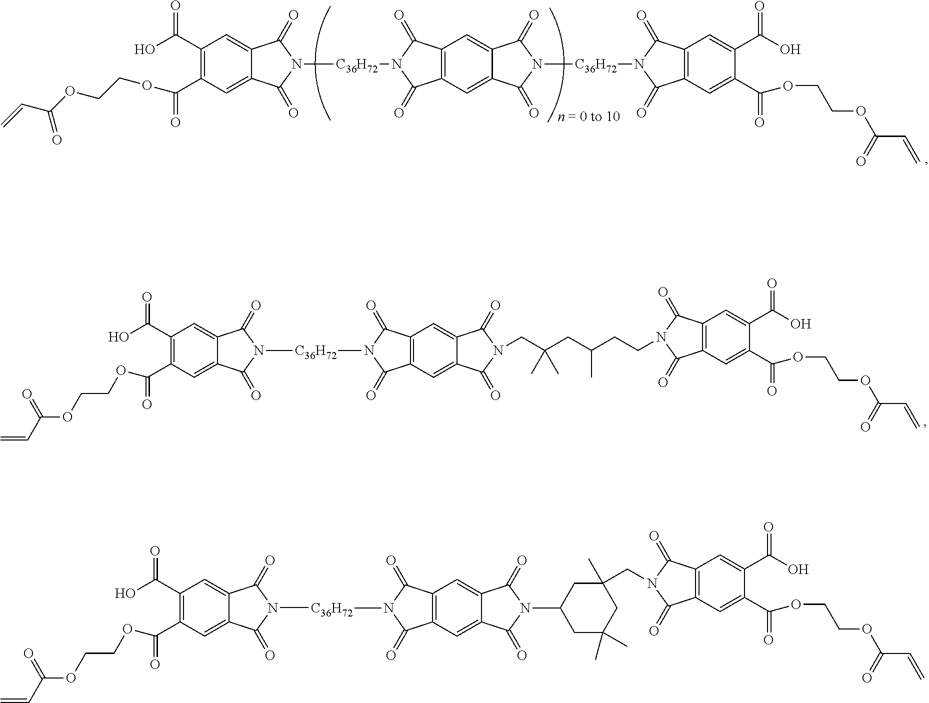

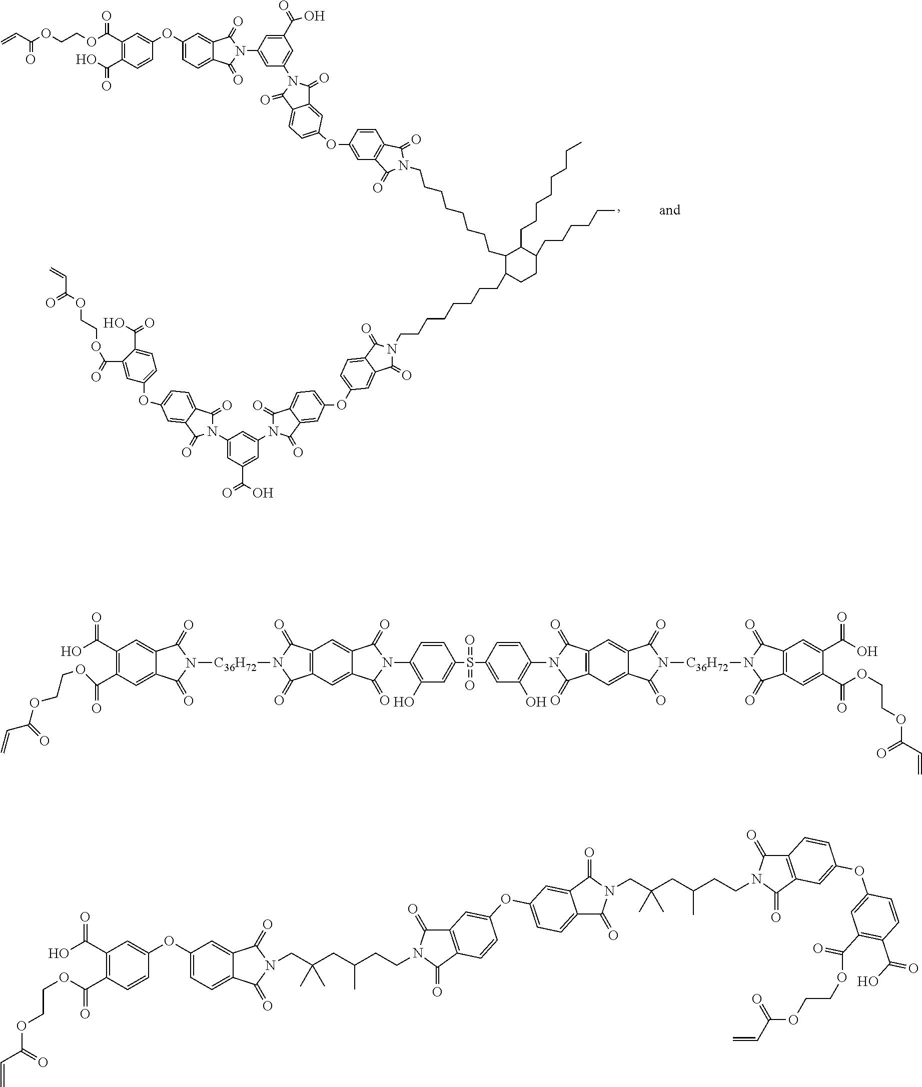

Further contemplated by the invention are certain functionalized polyimides where R₁ is an aromatic moiety, such as:

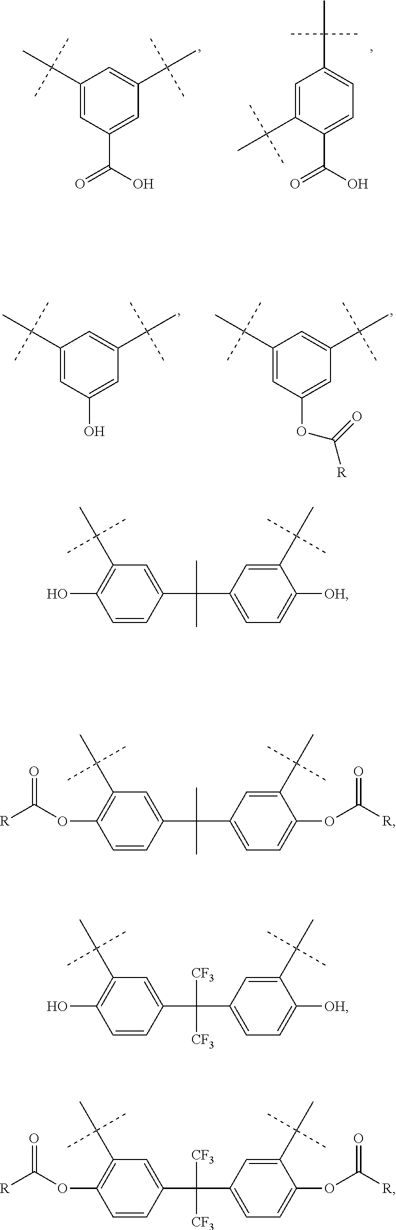

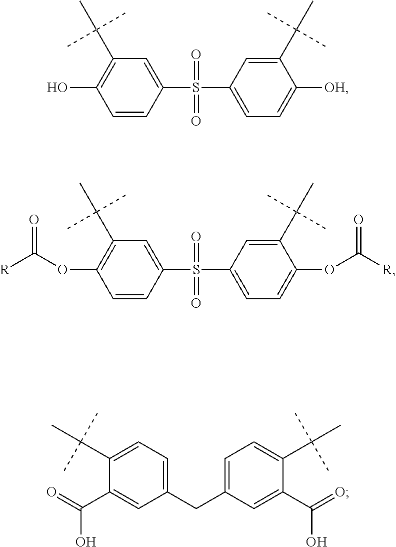

### DETAILED DESCRIPTION OF THE INVENTION

Unless specific definitions are provided, the nomenclatures utilized in connection with, and the laboratory procedures and techniques of analytical chemistry, synthetic organic and inorganic chemistry described herein are those known in the art, such as those set forth in “IUPAC Compendium of Chemical Terminology: IUPAC Recommendations (The Gold Book)” (McNaught ed.; International Union of Pure and Applied Chemistry, 2^{nd} Ed., 1997) and “Compendium of Polymer Terminology and Nomenclature: IUPAC Recommendations 2008” (Jones et al., eds; International Union of Pure and Applied Chemistry, 2009). Standard chemical symbols are used interchangeably with the full names represented by such symbols. Thus, for example, the terms “hydrogen” and “H” are understood to have identical meaning. Standard techniques may be used for chemical syntheses, chemical analyses, and formulation.

### DEFINITIONS

“About” as used herein means that a number referred to as “about” comprises the recited number plus or minus 1-10% of that recited number. For example, “about” 100 degrees can mean 95-105 degrees or as few as 99-101 degrees depending on the situation. Whenever it appears herein, a numerical range such as “1 to 20” refers to each integer in the given range; e.g., “1 to 20 carbon atoms” means that an alkyl group can contain only 1 carbon atom, 2 carbon atoms, 3 carbon atoms, etc., up to and including 20 carbon atoms (although the term “alkyl” also includes instances where no numerical range of carbon atoms is designated).

“Adhesive” or “adhesive compound” as used herein, refers to any substance that can adhere or bond two items together. Implicit in the definition of an “adhesive composition” or “adhesive formulation” is the fact that the composition or formulation is a combination or mixture of more than one species, component or compound, which can include adhesive monomers, oligomers, and/or polymers along with other materials, whereas an “adhesive compound” refers to a single species, such as an adhesive polymer or oligomer.

More specifically, adhesive composition refers to un-cured mixtures in which the individual components in the mixture retain the chemical and physical characteristics of the original individual components of which the mixture is made. Adhesive compositions are typically malleable and may be liquids, paste, gel or another form that can be applied to an item so that it can be bonded to another item.

“Cured adhesive,” “cured adhesive composition” or “cured adhesive compound” refers to adhesives components and mixtures obtained from reactive curable original compound(s) or mixture(s) thereof which have undergone a chemical and/or physical changes such that the original compound(s) or mixture(s) is (are) transformed into a solid, substantially non-flowing material. A typical curing process may involve cross-linking.

“Curable” means that an original compound(s) or composition material(s) can be transformed into a solid, substantially non-flowing material by means of chemical reaction, cross linking, radiation cross linking, or the like. Thus, adhesive compositions of the invention are curable, but unless otherwise specified, the original compound(s) or composition material(s) is (are) not cured.

“Functionalize” as used herein, refers to a process for adding a functional group to a compound. Thus, a “functionalized” compound is one in which a functional group has been added. A “functional group” refers to a specific grouping of elements that is characteristic of a class of compounds, and determines some properties and reactions of that class.

“Thermoset,” as used herein, refers to the ability of a compound, composition or other material to irreversibly “cure” resulting in a single three-dimensional network that has greater strength and less solubility compared to the non-cured product. Thermoset materials are typically polymers that may be cured, for example, through heat (e.g. above 200° Celsius), via a chemical reaction (e.g. epoxy ring-opening, free-radical polymerization, etc.), or through irradiation (e.g. visible light, U.V., or X-ray irradiation).

Thermoset materials, such as thermoset polymers or resins, are typically liquid or malleable forms prior to curing, and therefore may be molded or shaped into their final form, and/or used as adhesives. Curing transforms the thermoset resin into a rigid infusible and insoluble solid or rubber by a cross-linking process. Thus, energy and/or catalysts are typically added that cause the molecular chains to react at chemically active sites (unsaturated or epoxy sites, for example), linking the polymer chains into a rigid, 3-D structure. The cross-linking process forms molecules with a higher molecular weight and resultant higher melting point. During the reaction, when the molecular weight of the polymer has increased to a point such that the melting point is higher than the surrounding ambient temperature, the polymer becomes a solid material.

“Cross-linking,” as used herein, refers to the attachment of two or more oligomer or longer polymer chains by bridges of an element, a molecular group, a compound, or another oligomer or polymer. Crosslinking may take place upon heating; some crosslinking processes may also occur at room temperature or a lower temperature. As cross-linking density is increased, the properties of a material can be changed from thermoplastic to thermosetting.

The term “monomer” refers to a molecule that can undergo polymerization or copolymerization thereby contributing constitutional units to the essential structure of a macromolecule (a polymer).

“Polymer” and “polymer compound” are used interchangeably herein, to refer generally to the combined the products of a single chemical polymerization reaction. Combining monomer subunits into a covalently bonded chain produces polymers. Polymers that contain only a single type of monomer are known as “homopolymers,” while polymers containing a mixture of monomers are known as “copolymers.”

As used herein, “aliphatic” refers to any alkyl, alkenyl, cycloalkyl, or cycloalkenyl moiety.

“Aromatic hydrocarbon” or “aromatic” as used herein, refers to compounds having one or more benzene rings.

“Alkane,” as used herein, refers to saturated straight chain, branched or cyclic hydrocarbons having only single bonds. Alkanes have general formula CₙH₂ₙ₊₂.

“Cycloalkane,” refers to an alkane having one or more rings in its structure.

As used herein, “alkyl” refers to straight or branched chain hydrocarbyl groups having from 1 up to about 500 carbon atoms. “Lower alkyl” refers generally to alkyl groups having 1 to 6 carbon atoms. The terms “alkyl” and “substituted alkyl” include, respectively, substituted and unsubstituted C₁-C₅₀₀ straight chain saturated aliphatic hydrocarbon groups, substituted and unsubstituted C₂-C₂₀₀ straight chain unsaturated aliphatic hydrocarbon groups, substituted and unsubstituted C₄-C₁₀₀ branched saturated aliphatic hydrocarbon groups, substituted and unsubstituted C₁-C₅₀₀ branched unsaturated aliphatic hydrocarbon groups.

“Substituted alkyl” refers to alkyl moieties bearing substituents that include but are not limited to alkyl, alkenyl, alkynyl, hydroxy, oxo, alkoxy, mercapto, cycloalkyl, substituted cycloalkyl, heterocyclic, substituted heterocyclic, aryl, substituted aryl (e.g., arylC₁₋₁₀alkyl or arylC₁₋₁₀alkyloxy), heteroaryl, substituted heteroaryl (e.g., heteroarylC₁₋₁₀alkyl), aryloxy, substituted aryloxy, halogen, haloalkyl (e.g., trihalomethyl), cyano, nitro, nitrone, amino, amido, carbamoyl, ═O, ═CH—, —C(O)H, —C(O)O—, —C(O)—, —S—, —S(O)₂—, —OC(O)—O—, —NR—C(O)—, —NR—C(O)—NR—, —OC(O)—NR—, where R is H or lower alkyl, acyl, oxyacyl, carboxyl, carbamate, sulfonyl, sulfonamide, sulfuryl, C₁₋₁₀alkylthio, arylC₁₋₁₀alkylthio, C₁₋₁₀alkylamino, arylC₁₋₁₀alkylamino, N-aryl-N—C₁₋₁₀alkylamino, C₁₋₁₀alkyl carbonyl, arylC₁₋₁₀alkylcarbonyl, C₁₋₁₀alkylcarboxy, aryl C₁₋₁₀alkylcarboxy, C₁₋₁₀alkyl carbonylamino, aryl C₁₋₁₀alkylcarbonylamino, tetrahydrofuryl, morpholinyl, piperazinyl, and hydroxypyronyl.

In addition, as used herein “C₃₆” refers to all possible structural isomers of a 36 carbon aliphatic moiety, including branched isomers and cyclic isomers with up to three carbon-carbon double bonds in the backbone. One non-limiting example of a moiety that the definition of “C₃₆” refers to is the moiety comprising a cyclohexane-based core and four long “arms” attached to the core, as demonstrated by the following structure:

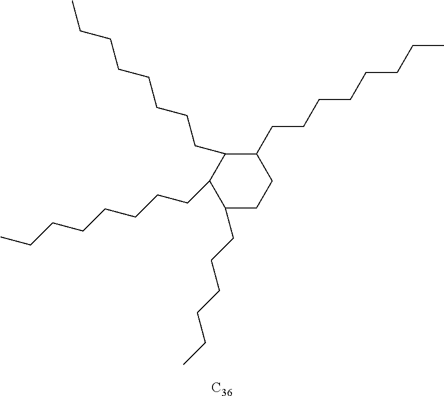 [SMILES: CCCCCCCCC1CCC(CCCCCC)C(CCCCCCCC)C1CCCCCCCC ; "C36"]

As used herein, “cycloalkyl” refers to cyclic ring-containing groups containing in the range of about 3 up to about 20 carbon atoms, typically 3 to about 15 carbon atoms. In certain embodiments, cycloalkyl groups have in the range of about 4 up to about 12 carbon atoms, and in yet further embodiments, cycloalkyl groups have in the range of about 5 up to about 8 carbon atoms. and “substituted cycloalkyl” refers to cycloalkyl groups further bearing one or more substituents as set forth below.

As used herein, the term “aryl” represents an unsubstituted, mono-, di- or tri-substituted monocyclic, polycyclic, biaryl aromatic groups covalently attached at any ring position capable of forming a stable covalent bond, certain preferred points of attachment being apparent to those skilled in the art (e.g., 3-phenyl, 4-naphtyl and the like).

As used herein, “hetero” refers to groups or moieties containing one or more heteroatoms such as N, O, Si and S. Thus, for example “heterocyclic” refers to cyclic (i.e., ring-containing) groups having e.g. N, O, Si or S as part of the ring structure, and having in the range of 3 up to 14 carbon atoms. “Heteroaryl” and “heteroalkyl” moieties are aryl and alkyl groups, respectively, containing e.g. N, O, Si or S as part of their structure. The terms “heteroaryl”, “heterocycle” and “heterocyclic” refer to a monovalent unsaturated group having a single ring or multiple condensed rings, from 1 to 8 carbon atoms and from 1 to 4 hetero atoms selected from nitrogen, sulfur or oxygen within the ring.

Hetero-containing groups may also be substituted. For example, “substituted heterocyclic” refers to a ring-containing group having in the range of 3 up to 14 carbon atoms that contains one or more heteroatoms and also bears one or more substituents, as set forth above.

As used herein, the term “phenol” includes compounds having one or more phenolic functions per molecule. The terms aliphatic, cycloaliphatic and aromatic, when used to describe phenols, refers to phenols to which aliphatic, cycloaliphatic and aromatic residues or combinations of these backbones are attached by direct bonding or ring fusion.

As used herein, “alkenyl,” “alkene” or “olefin” refers to straight or branched chain unsaturated hydrocarbyl groups having at least one carbon-carbon double bond, and having in the range of about 2 up to 500 carbon atoms. “Substituted alkenyl” refers to alkenyl groups further bearing one or more substituents as set forth above.

As used herein, “alkylene” refers to a divalent alkyl moiety, and “oxyalkylene” refers to an alkylene moiety containing at least one oxygen atom instead of a methylene (CH₂) unit. “Substituted alkylene” and “substituted oxyalkylene” refer to alkylene and oxyalkylene groups further bearing one or more substituents as set forth above.

As used herein, “acyl” refers to alkyl-carbonyl species.

“Allyl” as used herein, refers to refers to a compound bearing at least one moiety having the structure:

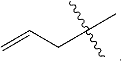 [SMILES: *CC=C]

“Imide” as used herein, refers to a functional group having two carbonyl groups bound to a primary amine or ammonia.

“Polyimides” are polymers of imide-containing monomers. Polyimides are typically linear or cyclic. Non-limiting examples of linear and cyclic (e.g. an aromatic heterocyclic polyimide) polyimides are shown below for illustrative purposes.

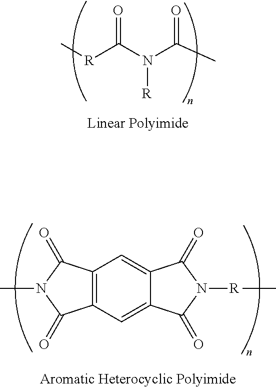

“Maleimide,” as used herein, refers to an N-substituted maleimide having the formula as shown below:

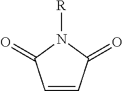

where R is an aromatic, heteroaromatic, aliphatic, or polymeric moiety.

“Bismaleimide” or “BMI”, as used herein, refers to compound in which two imide moieties are linked by a bridge, i.e. a compound a polyimide having the general structure shown below:

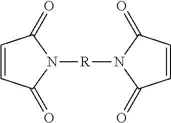

where R is an aromatic, heteroaromatic, aliphatic, or polymeric moiety.

BMIs can cure through an addition rather than a condensation reaction, thus avoiding problems resulting from the formation of volatiles. BMIs can be cured by a vinyl-type polymerization of a pre-polymer terminated with two maleimide groups.

As used herein, the term “acrylate” refers to a compound bearing at least one moiety having the structure:

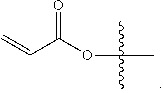 [SMILES: *OC(=O)C=C]

As used herein, the term “acrylamide” refers to a compound bearing at least one moiety having the structure:

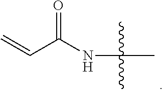 [SMILES: *NC(=O)C=C]

As used herein, the term “methacrylate” refers to a compound bearing at least one moiety having the structure:

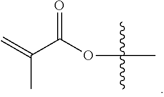 [SMILES: *OC(=O)C(=C)C]

As used herein, the term “methacrylamide” refers to a compound bearing at least one moiety having the structure:

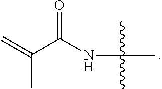 [SMILES: *NC(=O)C(=C)C]

As used herein, “maleate” refers to a compound bearing at least one moiety having the structure:

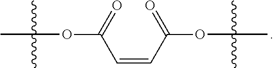 [SMILES: *OC(=O)/C=C\C(=O)O*]

As used herein, the term “acyloxy benzoate” or “phenyl ester” refers to a compound bearing at least one moiety having the structure:

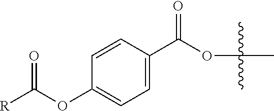

wherein R═H, lower alkyl, or aryl.

As used herein, the term “citraconimide” refers to a compound bearing at least one moiety having the structure:

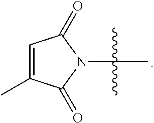 [SMILES: *N1C(=O)C=C(C)C1=O]

“Itaconate”, as used herein refers to a compound bearing at least one moiety having the structure:

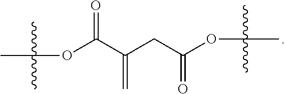 [SMILES: *OC(=O)CC(=C)C(=O)O*]

As used herein, the terms “halogen,” “halide,” or “halo” include fluorine, chlorine, bromine, and iodine.

As used herein, “siloxane” refers to any compound containing a Si—O moiety. Siloxanes may be either linear or cyclic. In certain embodiments, siloxanes of the invention include 2 or more repeating units of Si—O. Exemplary cyclic siloxanes include hexamethylcyclotrisiloxane, octamethylcyclotetrasiloxane, decamethylcyclopentasiloxane, dodecamethylcyclohexasiloxane and the like.

As used herein, “oxiranylene” or “epoxy” refers to divalent moieties having the structure:

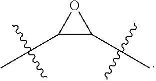 [SMILES: *C1OC1*]

The term “epoxy” also refers to thermosetting epoxide polymers that cure by polymerization and crosslinking when mixed with a catalyzing agent or “hardener,” also referred to as a “curing agent” or “curative.” Epoxies of the present invention include, but are not limited to aliphatic, cycloaliphatic, glycidyl ether, glycidyl ester, glycidyl amine epoxies, and the like, and combinations thereof.

As used herein, the term “oxetane” refers to a compound bearing at least one moiety having the structure:

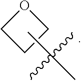

As used herein, the term “vinyl ether” refers to a compound bearing at least one moiety having the structure:

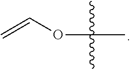 [SMILES: *OC=C]

As used herein, the term “vinyl ester” refers to a compound bearing at least one moiety having the structure:

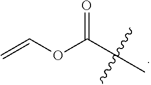 [SMILES: *C(=O)OC=C]

As used herein, “styrenic” refers to a compound bearing at least one moiety having the structure:

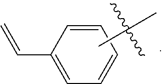

“Fumarate” as used herein, refers to a compound bearing at least one moiety having the structure:

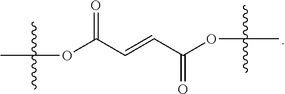 [SMILES: *OC(=O)/C=C/C(=O)O*]

As used herein, the term “free radical initiator” refers to any chemical species that, upon exposure to sufficient energy (e.g., light, heat, or the like), decomposes into parts, which are uncharged, but every one of such part possesses at least one unpaired electron.

As used herein, the term “coupling agent” refers to chemical species that are capable of bonding to a mineral surface and which also contain polymerizably reactive functional group(s) so as to enable interaction with the polyimide composition. Coupling agents thus facilitate linkage of the passivation layer to the substrate to which it is applied.

Thermogravimetric analysis” or “TGA” refers to a method of testing and analyzing a material to determine changes in weight of a sample that is being heated in relation to change in temperature. “Decomposition onset” refers to a temperature when the loss of weight in response to the increase of the temperature indicates that the sample is beginning to degrade.

“Passivation” as used herein, refer to the process of making a material “passive” in relation to another material or condition. “Passivation layers” are commonly used to encapsulate semiconductor devices, such as semiconductor wafers, to isolate the device from its immediate environment and, thereby, to protect the device from oxygen, water, etc., as well airborne or space-borne contaminants, particulates, humidity and the like. Passivation layers are typically formed from inert materials that are used to coat the device. This encapsulation process also passivates semiconductor devices by terminating dangling bonds created during manufacturing processes and by adjusting the surface potential to either reduce or increase the surface leakage current associated with these devices.

“Glass transition temperature” or “T_{g}” is used herein to refer to the temperature at which an amorphous solid, such as a polymer, becomes brittle on cooling, or soft on heating. More specifically, it defines a pseudo second order phase transition in which a supercooled melt yields, on cooling, a glassy structure and properties similar to those of crystalline materials e.g. of an isotropic solid material.

According to various embodiments of the present invention, there is provided devices comprising a semiconductor wafer or other substrate and a passivation layer disposed on the surface of the wafer or substrate. The passivation layer is comprised of a pre-imidized or partially imidized backbone with a photopolymerizable functional group, according to the structures I, II or III.

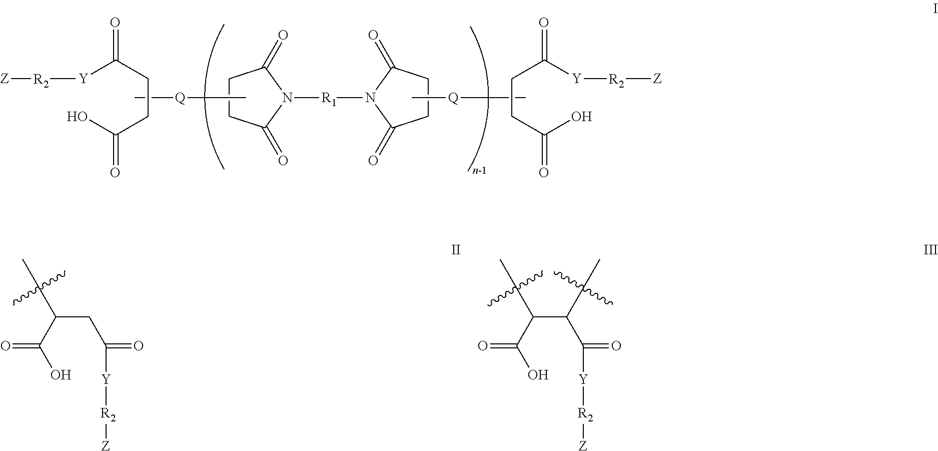

wherein, each R₁, R₂, and Q is independently selected from the group consisting of substituted or unsubstituted aliphatic, alkenyl, aromatic, heteroaromatic and siloxane moieties, Y is a heteroatom, Z is a polymerizable moiety, n is an integer having the value between 1 to about 10, and the symbol “ [symbol] ” depicts schematically a macromolecular chain to which the structure II or III is covalently attached.

In certain embodiments of the invention the R₁, R₂, and Q in structures II, III, and I can be an unsubstituted aromatic or heteroaromatic moiety having between 6-14 carbons. In another embodiment each R₁, R₂, and Q can be substituted or unsubstituted siloxane moiety having between 2 and about 50 silicon atoms. Such a siloxane moiety can be a polysiloxane, for example, a polysiloxane comprising repeating units selected from dimethylsiloxane, methylphenylsiloxane, diphenylsiloxane or combination thereof.

In some embodiments of structures I-III, substituted aliphatic, aromatic, heteroaromatic, or siloxane moieties may comprise substituents selected from an alkyl, an alkenyl, an alkynyl, hydroxyl, oxo, an alkoxy, mercapto, a cycloalkyl, a substituted cycloalkyl, a heterocyclic, a substituted heterocyclic, an aryl, a substituted aryl, a heteroaryl, a substituted heteroaryl, an aryloxy, a substituted aryloxy, a halogen, a haloalkyl, cyano, nitro, nitrone, an amino, an amido, —C(O)H, —C(O)—, —C(O)—O—, —S—, —S(O)2-, —OC(O)—O—, —NR—C(O)—, —NR—C(O)—NR—, and —OC(O)—NR—, wherein R can be any of H, a lower alkyl, an acyl, an oxyacyl, carboxyl, carbamate, sulfonyl, sulfonamide or sulfuryl.

In certain embodiments, the present invention provides chain-propagated polyimides polymers having a flexible aliphatic backbone in place of the traditional aromatic ether backbone found in conventional polyimide polymers have the same high temperature resistance due to their imide linkages, invention polyimide polymers display lower shrinkage than conventional polyimide polymers due to the chain propagation mechanism, thereby reducing stress on a wafer passivated with such polymers. Taken together, the methods and materials of the invention reduce the potential for delamination and warpage of semiconductor interconnection layers.

The polyimides that are utilized in the embodiments of the present invention to prepare the passivation layer are less subject to stress effects than previously used polyimides; therefore, the polyimides used in the present invention are compatible with very thin silicon wafers. The polyimides of the present invention are partially imidized, and are soluble in common organic solvents such as toluene and ketones required for the coating application. Furthermore, the end groups are functionalized with carboxylic acid which makes them aqueous developable.

Another desirable feature of the polyimides of the invention is that they have much lower moisture uptake than traditional polyimide passivation coatings. A further attractive feature of invention polyimides is they are optionally photoimagable, thereby allowing for patterning of the passivation layer.

Invention polyimides are readily prepared by a two-step one-pot reaction. In one embodiment of the invention a diamine is added to an excess of dianhydride in a suitable solvent. The mixture is heated to reflux and the condensation reaction proceeds to produce an anhydride-capped polyimide. The anhydride is then reacted with an appropriate alcohol, amine or thiol functionalized with a photocurable end group. An example compound of the invention would be hydroxyethyl acrylate. The terminal positions of the polyimide would have carboxylic acid functionality as well as acrylate. Most of the invention compounds produced would have high molecular weight, so that it is simple to isolate the product by precipitation in a suitable solvent such as methanol, acetone, water, and such. This is also a very good and practical method to purify the compounds, because any small hydrophilic materials would be soluble in such solvents and leave behind the desired product.

A wide variety of diamines are contemplated for use in the practice of the invention, such as for example, 1,10-dimainodecane; 1,12-diaminodecane; dimer diamine; 1,2-diamino-2-methylpropane; 1,2-diaminocyclohexane; 1,2-diaminopropane; 1,3-diaminopropane; 1,4-diaminobutane, 1,5-diaminopentane; 1,6-diaminohexane; 1,7-diaminoheptane; 1,8-diaminooctane; 1,9-diaminononane; 3,3′-diamino-N-methyldipropylamine; diaminomaleonitrile; 1,3-diaminopentane; 9-10-diaminophenanthrene; 4,4′-diaminooctafluorobiphenyl; 3,5-diaminobenzoic acid; 3,7-diamino-2-methoxyfluorene; 4,4′-diaminobenzophenone; 3,4-diaminobenzophenone; 3,4-diaminotoluene; 2,6-diaminoanthroquinone; 2,6-diaminotoluene; 2,3-diaminotoluene; 1,8-diaminonaphthalene; 2,4-cumenediamine; 1,3-bisaminomethylbenzene; 1,3-bisaminomethylcyclohexane; 2-chloro-1,4-diaminobenzene; 1,4-diamino-2,5-dichlorobenzene; 1,4-diamino-2,5-dimethylbenzene; 4,4′-diamino-2,2′-bistrifluoromethylbisphenyl; bis(amino-3-chlorophenyl)ethane; bis(4-amino-3,5-dimethylphenyl)methane; bis(4-amino-3,5-diethylphenyl)methane; bis(4-amino-3-ethylphenyl)methane; bis(4-amino-3-ethyl)diaminofluorene; diaminobenzoic acid; 2,3-diamononaphtalene; 2,3-diaminophenol; bis(4-amino-3-methylphenyl)methane; bis(4-amino-3-ethylphenyl)methane; 4,4′-diaminophenylsulfone; 4,4′-oxydianiline; 4,4′-diaminodiphenyl sulfide; 3,4′-oxydianiline; 2,2-bis[4-(3-aminophenoxyl)phenyl]propane; 2,2′-bis[4-(4-aminophenoxyl)phenyl]propane; 1,3-bis(4-aminophenoxy)benzene; 4,4′-bis(aminophenoxy)bisphenyl; 4,4′-diamino-3,3′-dihydroxybiphenyl; 4,4′-diamino-3,3′-dimethylbiphenyl; 4,4′-diamino-3,3′-dimethyoxybiphenyl; Bisaniline M; Bisaniline P; 9,9-bis(4-aminophenyl)fluorine; o-toluidine sulfone; methylene bis(anthranilic acid); 1,3-bis(4-aminophenoxy)-2,2-dimethylpropane; 1,3-bis(4-aminophenoxy)propane; 1,4-bis(aminophenoxy)butane; 1,5-bis(4-aminophenoxy)butane; 2,3,5′-tetramethylbenzidine; 4,4′-diaminobenzanilide; 2,2-bis(4-aminophenyl)hexafluoropropane; bis(3-amino-4-hyroxyphenyl)sulfone; 9,9-bis(3-amino-4-hydroxyphenyl)fluorene; 2,2-bis(3-amino-4-hydroxyphenyl)hexafluoropropane; 2,2-bis(3-amino-4-hydroxyphenyl)propane polyalkylenediamines (e.g. Huntsman's Jeffamine D-230, D-400, D2000, and D-4000 products); 1,3-cyclohexanebis(methylamine); m-xylenediamine; p-xylenediamine; bis(4-amino-3-methylcyclohexyl)methane; 1,2-bis(2-aminoethoxy)ethane; 3(4),8(9)-bis(aminomethyl)tricycle(5.2.1.0)decane; and the like.

A wide variety of anhydrides are contemplated for use in the practice of the invention, such as, for example, polybutadiene-graft-maleic anhydride; polyethylene-graft-maleic anhydride; polyethylene-alt-maleic anhydride; polymaleic anhydride-alt-1-octadecene; polypropylene-graft-maleic anhydride; poly(styrene-co-maleic anhydride); pyromellitic dianhydride; 1,2,3,4-cyclobutanetetracarboxylic dianhydride; 1,4,5,8-naphtalenetetracarboxylic dianhydride; 3,4,9,10-perylenetetracraboxylic dianhydride; bicyclo(2.2.2)oct-7-ene-2,3,5,6-tetracarboxylic dianhydride; diethylenetriaminepentaacetic dianhydride; ethylenediaminetetracetic dianhydride; 3,3′,4,4′-benzophenone tetracarboxylic dianhydride; 3,3′,4,4′-biphenyl tetracarboxylic dianhydride; 4,4′-oxydiphthalic dianhydride; 3,3′,4,4′-diphenylsulfone tetracarboxylic dianhydride; 2,2′-bis(3,3-dicarboxyphenyl)hexafluoropropane dianhydride; 4,4′-bisphenol A diphthalic dianhydride; 5-(2,5-dioxytetrahydro)-3-methyl-3-cyclohexene-1,2-dicarboxylic anhydride; and the like.

Additional dianhydrides contemplated for use in the present invention include, but are not limited to:

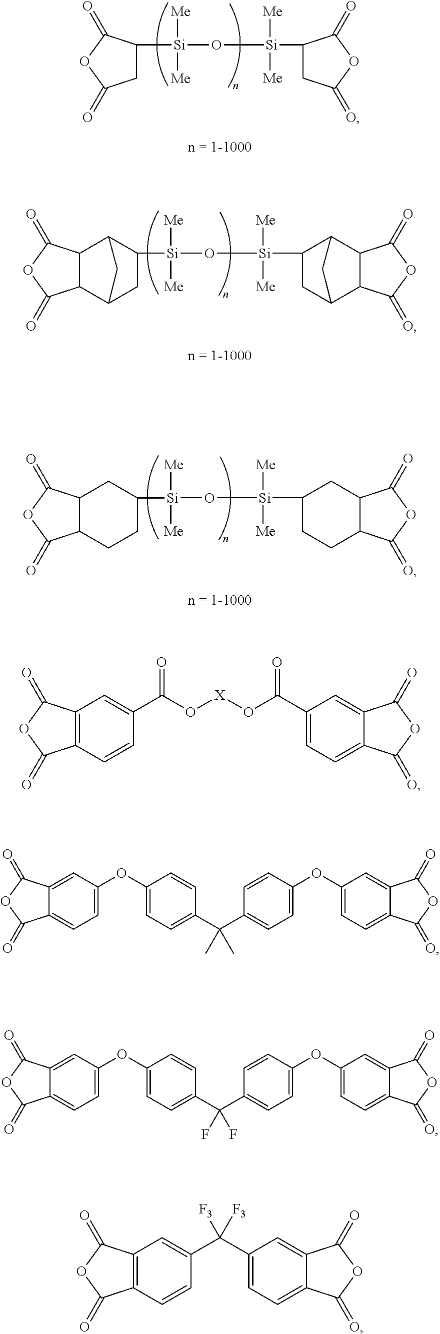

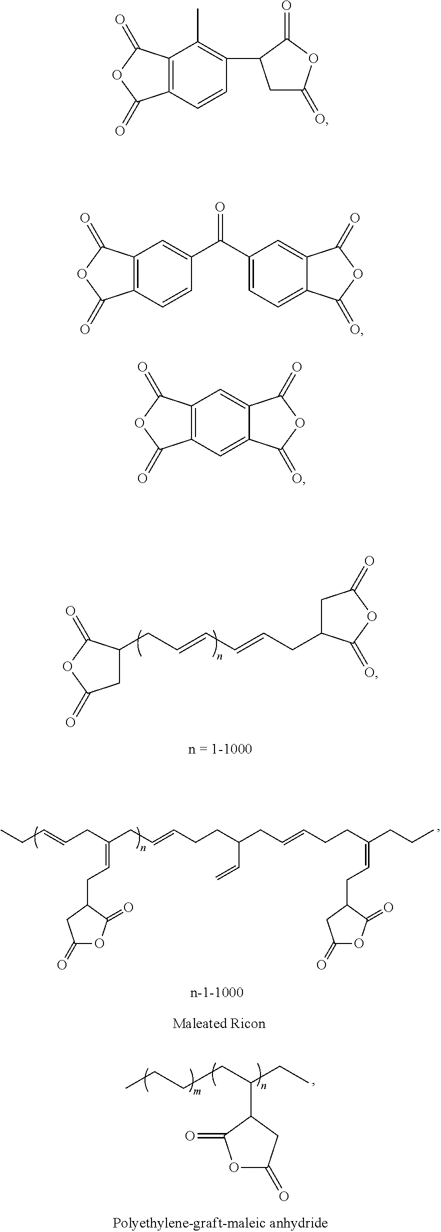

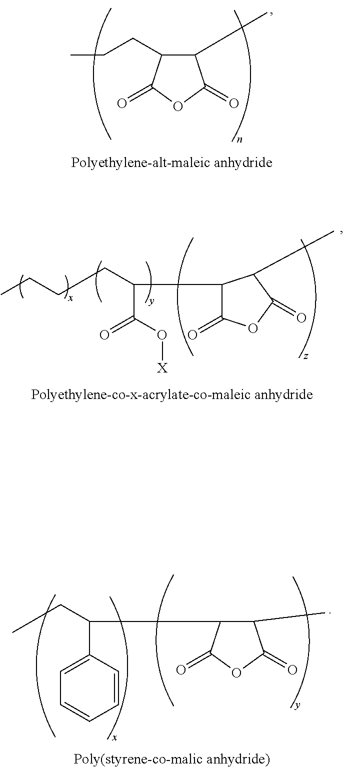

wherein X is saturated, unsaturated, strait or branched alkyl, polyester, polyamide, polyether, polysiloxane or polyurethane.

A wide variety of functional groups are contemplated for use as photoimagable end groups for the polyimides of the invention. After the condensation reaction of the diamine with excess dianhydride a polyimide molecule is formed that is capped with anhydride groups, this can be reacted with photocurable-functionalized alcohols, thiols or amines to produce the product of the invention. Such photocurable functionalized compounds include but are not limited to, hydroxyethyl (meth)acrylate; hydroxypropyl (meth)acrylate; hydroxybutyl (meth)acrylate, hydroxycyclohexyl (meth)acrylate, hydroxybutyl mono-vinyl ether, cyclohexane dimethanol mono-vinyl ether, 3-aminopropyl vinyl ether, polycaprolactone acrylate, polyethylene glycol mono-methacrylate, and the like. Some of the specific non-limiting functional groups are illustrated below, wherein n and m are from 0 to about 10.

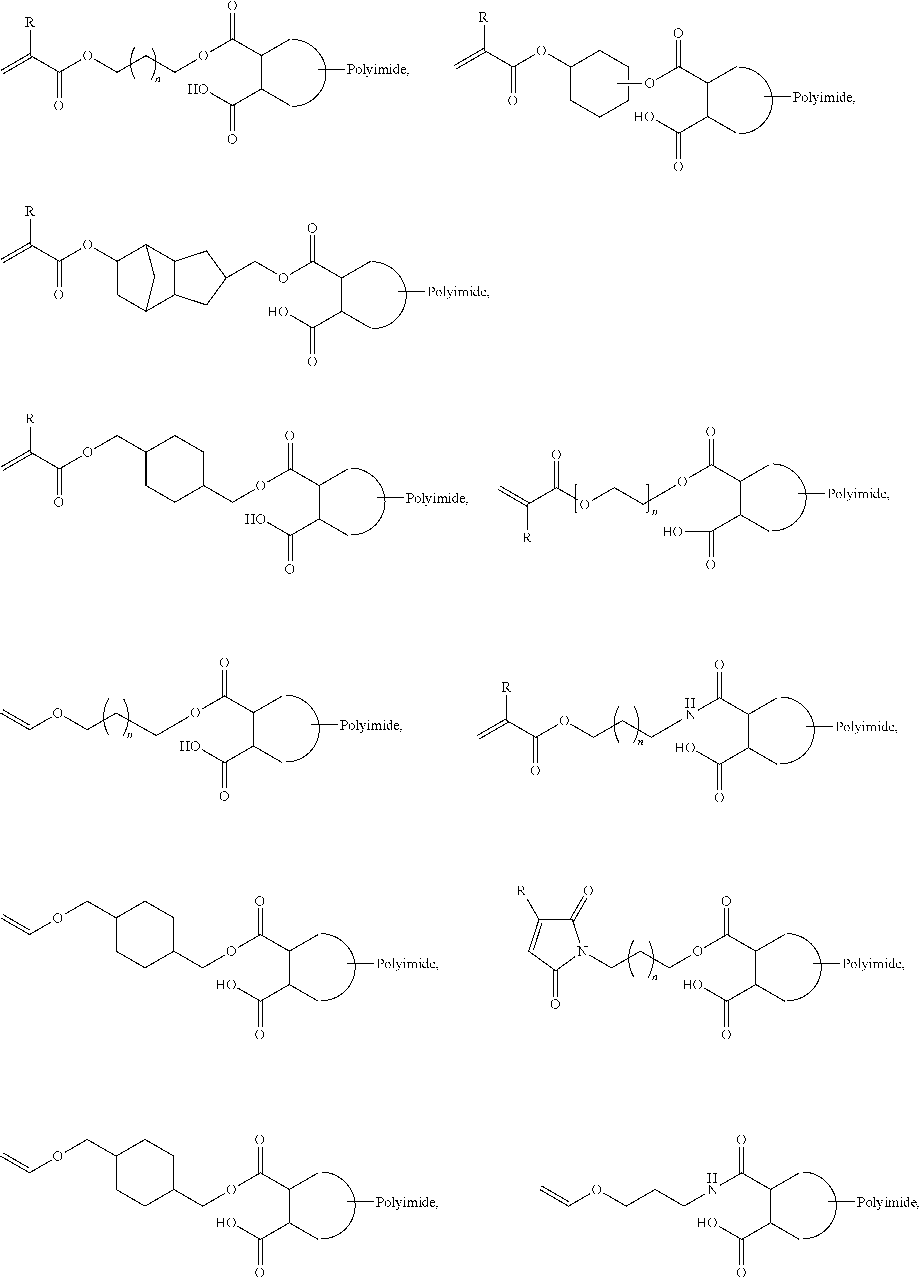

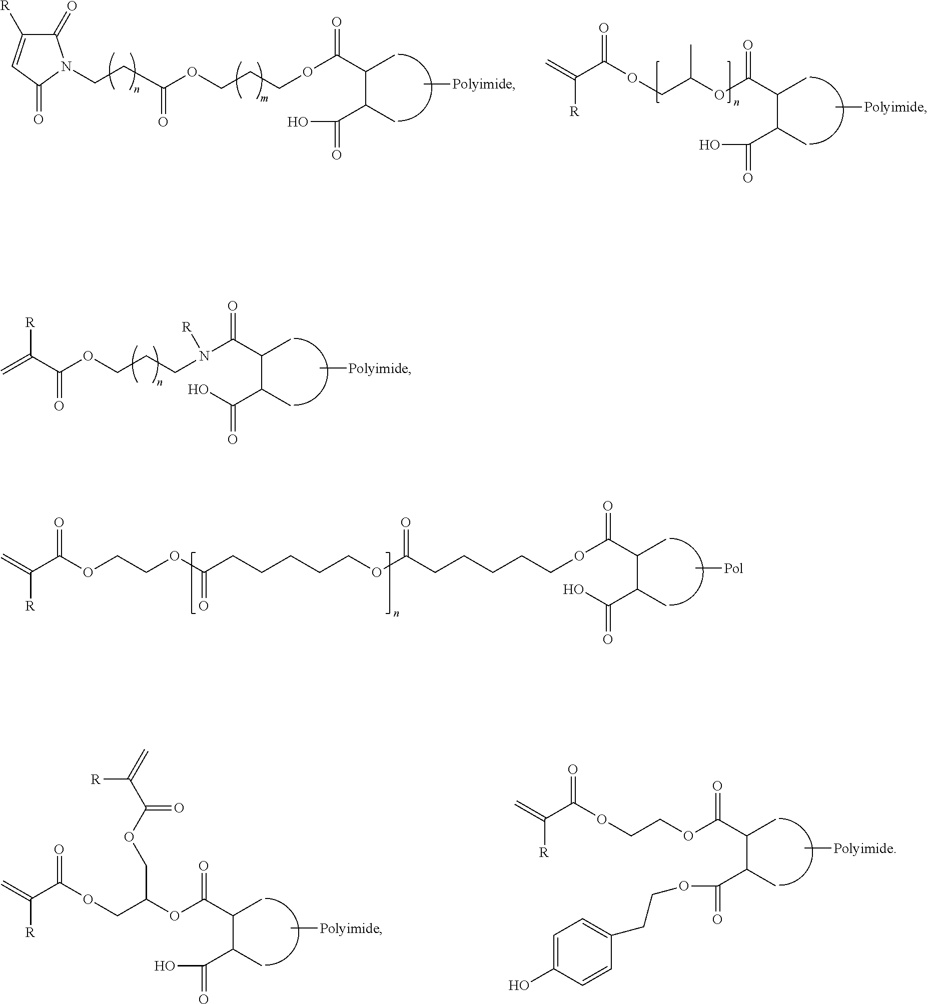

Many of the compounds of the invention are based on flexible aliphatic diamines. Dimer diamine, which is a C₃₆ mixture of branched compounds is derived from dimerization of aliphatic C₁₈ fatty acids, which are converted to diamide, followed by the reduction to afford the diamine. This compounds is available in several grades including unsaturated and saturated fully hydrogenated versions. All of the different grades of dimer diamine are contemplated for use in the invention.

An exemplary compound of the invention is based on the condensation reaction of dimer diamine with an excess of pyromellitic dianhydride. The solvent used in the reaction is typically toluene along with some N-methyl-2-pyrrolidone (NMP) to allow greater solubility. The azeotropic removal of the water produces an anhydride-terminated polyimide, which is reacted with hydroxyethyl acrylate in the presence of a trace amount of dimethylaminopyridine (DMAP) to produce the terminated acrylate acid polyimide. Pouring the solution into methanol isolates the product.

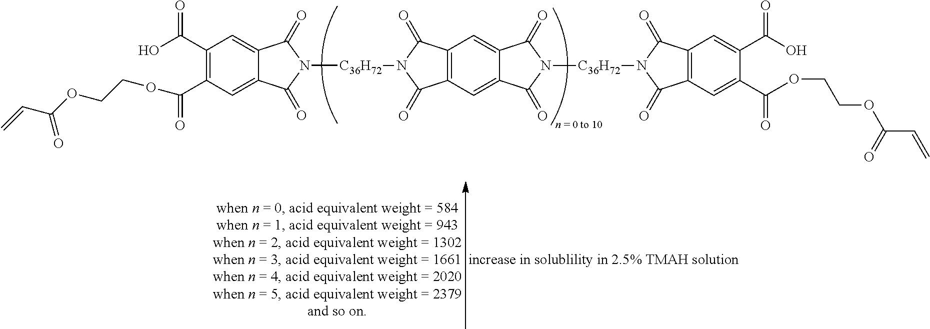

The reaction always produces a range of molecular weights. The higher the average molecular weight the less soluble the material becomes in dilute base solution, and therefore developing the film after UV exposure becomes more difficult. To produce a polyimide that has a low molecular weight distribution either the dianhydride or the diamine will have to be present in excess. The ideal compound should have an average acid equivalent weight of 500 to 1000 g/equivalent.

To achieve the desired anhydride-terminated polyimide, the dianhydride must be present in excess. Anywhere from 1.1 to 1 molar ratio of the dianhydride to the diamine up to 3 to 1 molar ratio of the dianhydride to the diamine. In some embodiments a 2 to 1 molar ratio of the dianhydride to the diamine is used, in most cases a 1.5 to 1 molar ratio of the dianhydride to the diamine is preferred.

The polyimides based on dimer diamine have very low modulus and are very hydrophobic, however, since the diamine has a very large molecular weight it often lacks solubility in dilute base. To overcome this problem, lower molecular weight diamines are incorporated into the oligomer. Using diamines such as 1,6-hexanedimaine, 2,2,4-trimethyl-1,6-hexane diamine, 1,8-octanediamine, 1,10-decanediamine, 1,12-dodecanedimaine, isophoronediamine and similar such compounds in small amounts increases the solubility of the polyimide in dilute aqueous base solution. Several exemplarity compounds of the invention are illustrated below. These compounds are mixtures of oligomers with molecular weight distributions; only the idealized structures are illustrated.

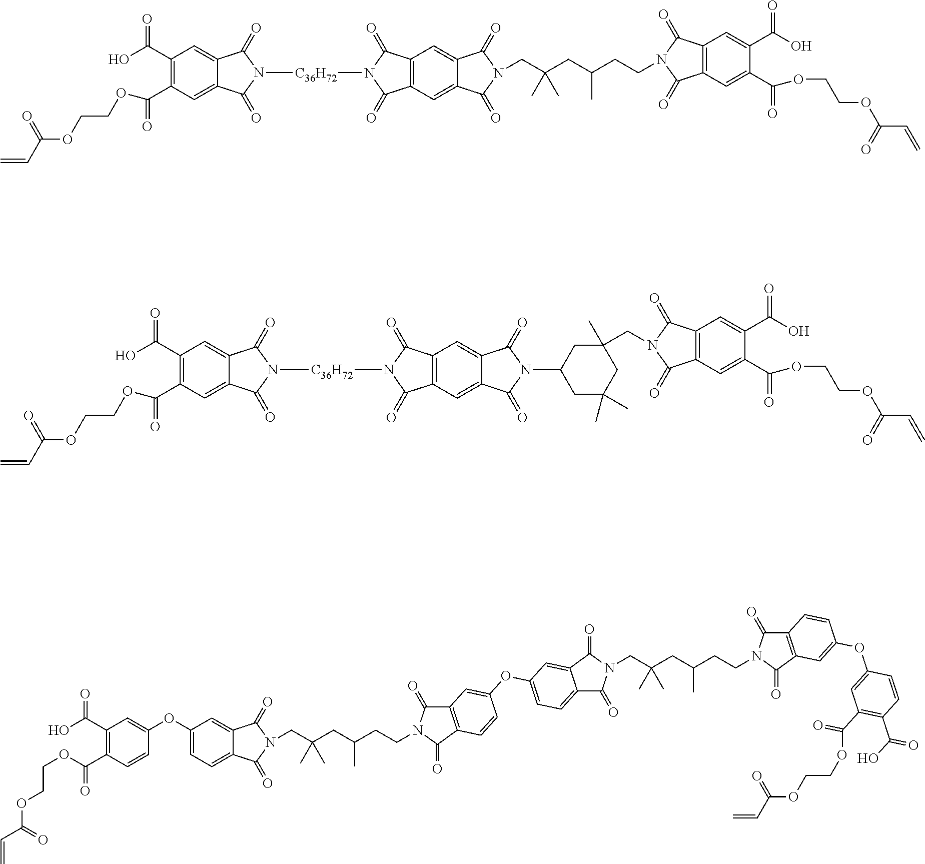

A variety of carboxyl-terminated polyimides can be synthesized using readily available dianhydrides and diamines With only two carboxyl groups per molecule, the molecular weight of the oligomer must be very small in order to be developable (soluble in an aqueous solution of dilute base). Also contemplated by the invention are higher molecular weight polyimide oligomers, however, in order to be developable in aqueous solution, additional hydrolyzable groups can be inserted into the polyimide. Compounds such as amidol, 2,4-diaminobenzoic acid, 3,5-diaminobenzoic acid, 2,2-bis(3-amino-4-hydroxyphenyl)sulfone, 2,2-bis(3-amino-4-hydroxyphenyl)propane and 2,2-bis(3-amino-4-hydroxyphenyl)hexafluoropropane can be reacted with a dianhydride to form a polyimide with multiple hydrolyzable groups to ease the development in aqueous solutions. The following are but a few non-limiting exemplary compounds of the invention containing multiple hydrolyzable functional groups. The illustrated compounds represent an idealized structure and just one of the many possible structures in the mixture.

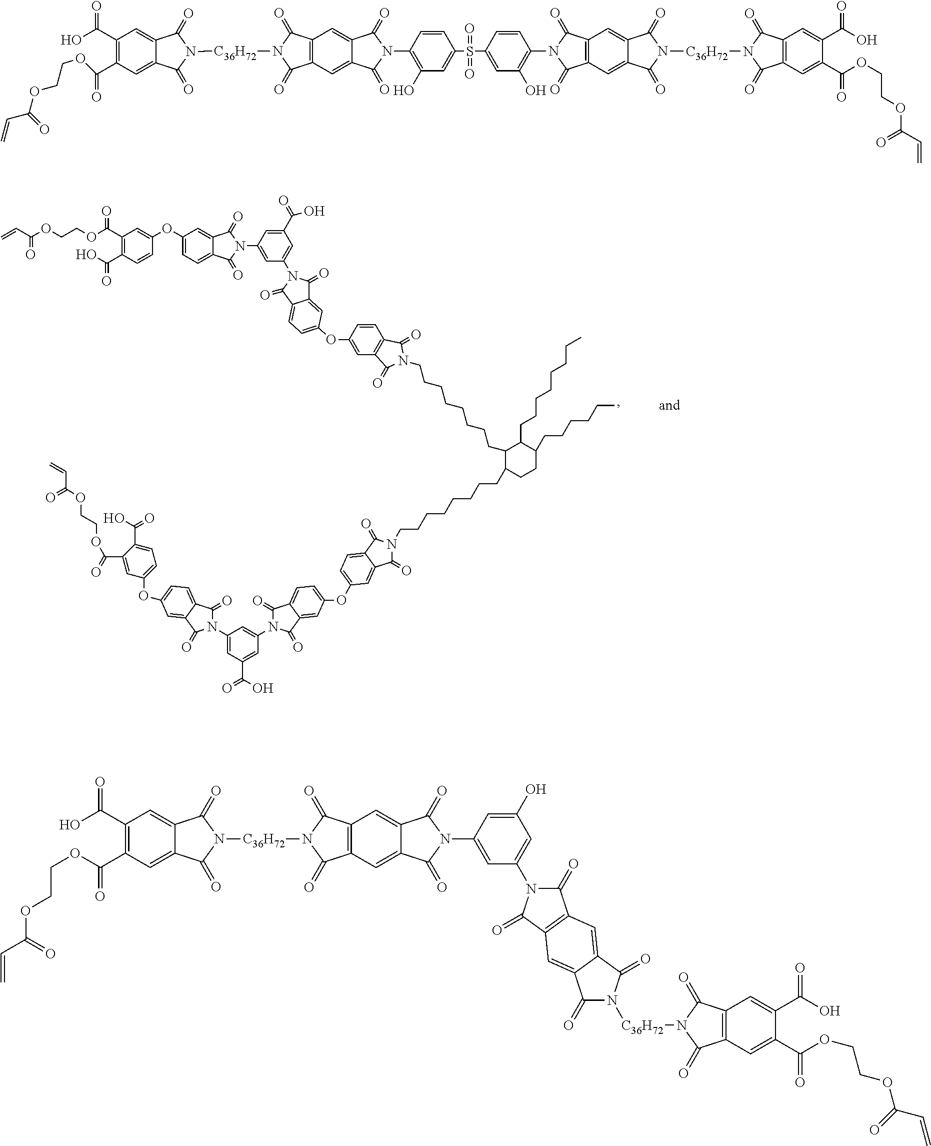

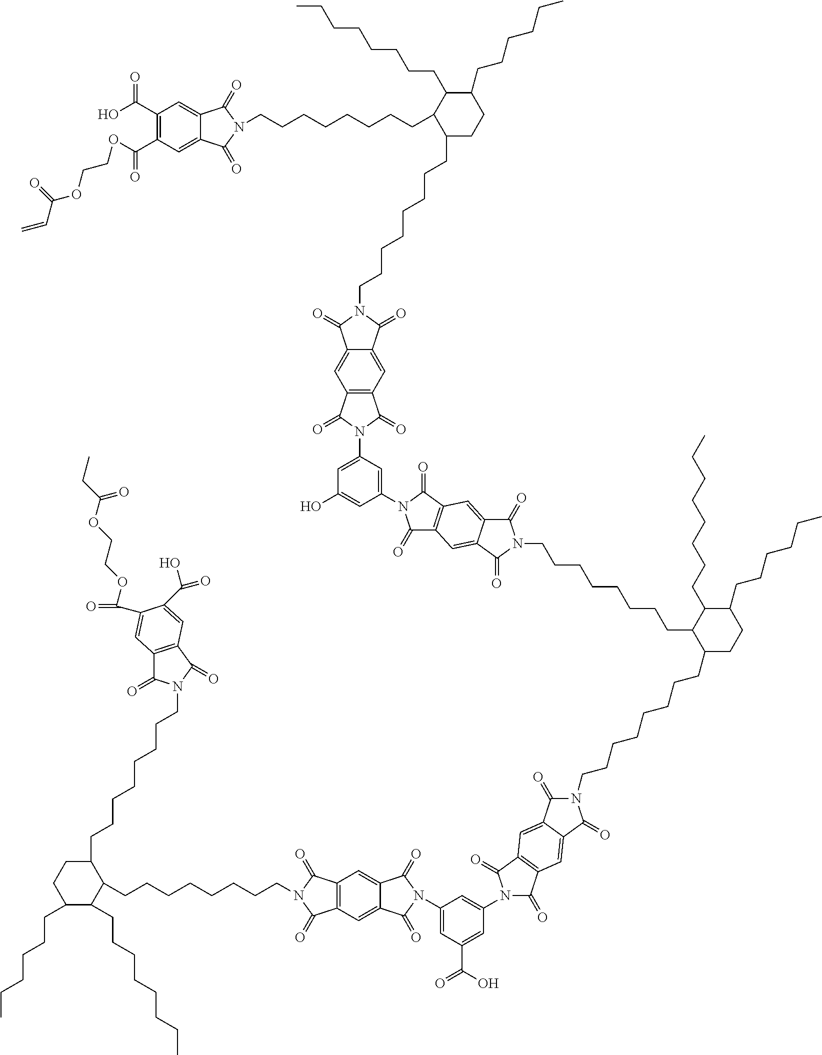 [SMILES: C=CC(=O)OCCOC(=O)c1cc2c(cc1C(=O)O)C(=O)N(CCCCCCCCC1C(CCCCCCCCn3c(=O)c4cc5c(=O)n(-c6cc(O)cc(-n7c(=O)c8cc9c(=O)n(CCCCCCCCC%10C(CCCCCCCCn%11c(=O)c%12cc%13c(=O)n(-c%14cc(C(=O)O)cc(-n%15c(=O)c%16cc%17c(=O)n(CCCCCCCCC%18C(CCCCCCCCN%19C(=O)c%20cc(C(=O)O)c(C(=O)OCCOC(=O)CC)cc%20C%19=O)CCC(CCCCCC)C%18CCCCCCCC)c(=O)c%17cc%16c%15=O)c%14)c(=O)c%13cc%12c%11=O)CCC(CCCCCC)C%10CCCCCCCC)c(=O)c9cc8c7=O)c6)c(=O)c5cc4c3=O)CCC(CCCCCC)C1CCCCCCCC)C2=O]

In another embodiment of the invention an excess diamine is reacted with a dianhydride and the polyamic acid is heated to reflux to remove water and form a polyimide that is amine terminated. The terminal amine can be further reacted with maleic anhydride or itaconic anhydride to form a polymerizable product with an aqueous-developable carboxyl group. Structural formulae IV and V below are illustrative of this type of product:

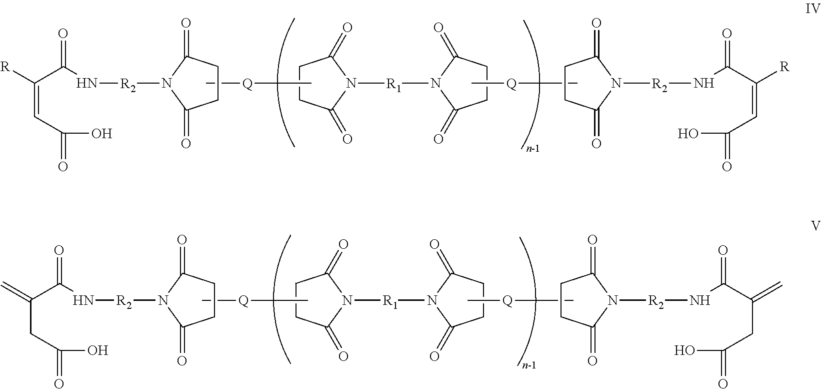

In another embodiment of the invention, an excess dianhydride is reacted with a diamine and the material is refluxed to close the polyamic acid to form an anhydride-terminated polyimide. The polyimide is then reacted further with an amino alcohol and refluxed again to form the alcohol-terminated polyimide. The terminal alcohol is then reacted further with maleic or itaconic anhydride to produce a polymerizable aqueous developable polyimide capped with a maleate or itaconate. Structural formulae VI and VII below illustrate this concept:

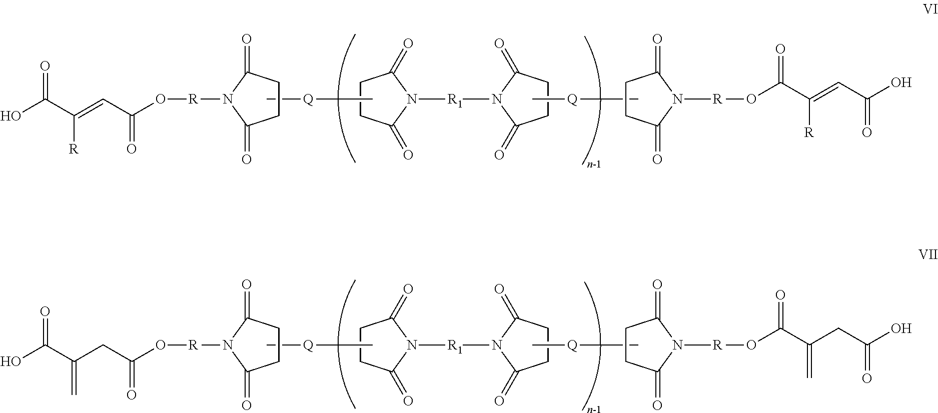

The present invention provides compositions containing at least one low modulus polyimide compound. For example, the low modulus polyimides may be used independently as the monomer in a polymeric composition, such as a wafer passivation composition, or may be combined with other materials and reagents to prepare wafer passivation compositions. The low modulus polyimides may be used as the sole photoimagable thermoset/monomer of a wafer passivation composition of the invention. In other embodiments, the low modulus polyimides may be combined with other monomers, such as thermoset monomers, to make fully formulated wafer passivation compositions. In yet another embodiment of the invention the low modulus polyimides may be used independently or in combination with other monomers, such as thermoset monomers, in a composition, which seals and protects a substrate.

In certain embodiments of the invention, the low modulus polyimide is present in a composition, such as a wafer passivation composition, in an amount of from 0.5 weight percent (wt %) to about 98 wt %, based on the total weight of the composition. Typically, the composition will contain an amount of the low modulus polyimide equal to at least about 40 wt %, often at least about 60 wt %, frequently at least about 80 wt %, and in some embodiments at least about 95 wt % based on the total weight of the composition (after all of the solvent has been removed).

In another embodiment of the invention, the composition containing the low modulus polyimide includes at least one co-monomer, which is typically present in an amount from 5 wt % to about 50 wt %, based on the total weight of the composition. In some aspects of the invention, the composition will contain an amount of the co-monomer equal to at least about 5 wt %, often at least about 10 wt %, frequently at least about 25 wt %, and in some embodiments at least about 30 wt % based on the total weight of the composition. Co-monomers suitable for use in the polyimide containing composition include but are not limited to, acrylates methacrylates, acrylamides, methacrylamides, cyanate esters, maleimides, vinyl ethers, vinyl esters, styrenic compounds, allyl functional compounds, epoxies, epoxy curatives, and olefins.

In certain embodiments, the present invention provides compositions, such as adhesive compositions, including at least one low modulus polyimide and at least one curing initiator. The curing initiator is typically present in adhesive compositions of the invention at an amount from 0.1 wt % to about 5 wt %, based on the total weight of the composition, and typically is a free-radical initiator. In some embodiments, the curing initiator is present in an amount at least about 0.5%, often at least about 1 wt %, frequently at least about 2 wt %, at some embodiments at least about 3 wt %, based on the total weight of the composition

Free-radical initiators contemplated for use in the practice of the invention typically decompose (i.e., have a half life in the range of about 10 hours) at temperatures in the range of about 70° C., up to 180° C. Exemplary free-radical initiators contemplated for use in the practice of the present invention include peroxides (e.g. dicumyl peroxide, dibenzoyl peroxide, 2-butanone peroxide, tert-butyl perbenzoate, di-tert-butyl peroxide, 2,5-bis(tert-butylperoxy)-2,5-dimethylhexane, bis(tert-butyl peroxyisopropyl)benzene, and tert-butyl hydroperoxide, azo compounds (e.g., 2,2′-azobis(2-methyl-propanenitrile), 2,2′-azobis(2-methylbutanenitrile), and 1,1′-azobis(cyclohexanecarbonitrile). Other free-radical initiators that will be well known in the art may also be suitable for use in the composition of the present invention.

Free radical initiators also include photoinitiators. For invention compositions that contain a photoinitiator, the curing process can be initiated, for example, by UV radiation. In one embodiment, the photoinitiator is present at a concentration of 0.1 wt % to 5-wt %, based on the total weight of the organic compounds in the composition (excluding any filler). In one embodiment, the photoinitiator comprises 0.5 wt % to 3.0 wt %, based on the total weight of the organic compounds in the composition. In other embodiments, the photoinitiator is present at least about 0.5 wt %, often at least about 1 wt %, frequently at least about 2 wt %, and in some embodiments at least about 3 wt %, based on the total weight of the organic compounds in the composition. Photoinitiators include benzoin derivatives, benzilketals, a,a-dialkoxyacetophenones, α-hydroxyalkylphenones, α-aminoalkylphenones, acylphosphine oxides, titanocene compounds, combinations of benzophenones and amines or Michler's ketone, and the like.

In some embodiments, both photoinitiation and thermal initiation may be desirable. For example, curing of a photoinitiator-containing adhesive can be started by UV irradiation, and in a later processing step, curing can be completed by the application of heat to accomplish a free-radical cure. Both UV and thermal initiators may therefore be added to the adhesive compositions of the invention.

In certain aspects, the compositions, such as adhesive compositions, of the invention include at least one additional compound that can co-cure with the low modulus polyimides. The additional compound is typically present in a wafer passivation composition from about 10-wt % to about 90 wt % based on total weight of the composition. In such aspects, the composition will typically contain an amount of the co-curing compound equal to at least about 20 wt %, often at least about 30 wt %, frequently at least about 40 wt %, and in some embodiments at least about 50 wt % based on the total weight of the composition.

Such compounds include, for example, epoxies (e.g. epoxies based on glycidyl ethers of alcohols, phenols, bisphenols, oligomeric phenolics, phenolic novolacs, cresolic novolacs, acrylates, methacrylates, maleimides, poly-phenol compounds (e.g. poly (4-hydroxystyrene)), anhydrides, dianhydrides, polyanhydrides such as styrene-maleic anhydride co-polymers, imides, carboxylic acids, dithiols, polythiols, phenol functional mono-maleimides, bismaleimides, polymaleimides, mono-itaconates, mono-maleates, mono-fumarates, acrylic acid, methacrylic acid, cyanate esters, vinyl ethers, vinyl esters, orphenol functional esters, ureas, amides, polyolefins (e.g. amine, carboxylic acid, hydroxy, and epoxy functional) siloxanes (e.g. epoxy, phenolic, carboxylic acid, or thiol functional), cyanoacrylates, allyl functional compounds and styrenic, as well as combinations thereof. In yet further embodiments, the invention provides cured adhesives prepared from compositions that include at least one low modulus polyimide.

In certain aspects, the adhesive compositions of the invention include at least one additional coupling agent. Exemplary coupling agents contemplated for use in the practice of the present invention include silicate esters, metal acrylate salts (e.g., aluminum methacrylate), titanates (e.g., titanium methacryloxyethylacetoacetate triisopropoxide), zirconates, or compounds that contain a copolymerizable group and a chelating ligand (e.g., phosphine, mercaptan, acetoacetate, and the like). In some embodiments, the coupling agent contains both a copolymerizable function (e.g., vinyl, acrylate, methacrylate, epoxy, thiol, anhydride, isocyanate, and phenol moieties) and a silicate ester function. The silicate ester portion of the coupling agent is capable of condensing with metal hydroxides present on the mineral surface of substrate, while the co-polymerizable function is capable of co-polymerizing with the other reactive components of invention wafer passivation compositions. In certain embodiments coupling agents contemplated for use in the practice of the invention are oligomeric silicate coupling agents such as poly (methoxyvinylsiloxane).

### Wafer Passivation

In certain embodiments, the present invention provides wafer passivation compositions that are of various forms and consistencies including, liquids, solutions, pastes and thermoplastic solids. In one embodiment, the wafer passivation composition is a solution containing a partially-imidized functionalized polyimide oligomer suitable for spin coating onto a wafer comprising multiple microelectronic devices.

In certain embodiments, a solvent may be employed in the practice of the invention. For example, when the wafer passivation compound is spin-coated onto a circular wafer, it is desirable to have an even coating throughout the entire wafer, i.e., the solvent or solvent system should have the ability to deliver the same amount of material to each point on the wafer. Thus, the wafer passivation compound will be evenly coated throughout, i.e., there will be the same amount of material at the center of the wafer as at the edges. Ideally, the solution of the wafer passivation compound is “Newtonian”, with a thixotropic slope of 1.0. In certain embodiments, the solutions used to dispense the wafer passivation compound have slopes ranging from 1.0 to about 1.2.

In some embodiments, the solvent or solvent system has a boiling point ranging from about 100° C. up to about 220° C. In some embodiments, the solvent is toluene, xylenes, cyclopentanone, cyclohexanone, tetralin, N-methylpyrrolidone, N,N-dimethylformamide, N,N-dimethylacetamide, diethylene glycol monomethylether, and the like.

In general, the wafer passivation compositions of the invention will photoimage under the influence of UV light at or near room temperature. All non-developed portions of the passivation film can then be removed via soaking in, or application of a jet spray of, an appropriate solvent or combination of solvents. For aqueous development the industry typically uses 2.5% aqueous solution of tetramethyl ammonium hydroxide, however, other aqueous solutions are also contemplated for use in the development of the invention compounds. These include, but are not limited to, sodium hydroxide, potassium hydroxide, tetraethyl ammonium hydroxide, tetrabutyl ammonium hydroxide and the like. The concentration of base can range from 0.5% up to 10% by weight aqueous solutions. The remaining photocured polyimide film could then be optionally fully cured via a post-bake at 180-200° C. for approximately fifteen minutes to one hour.

Inhibitors for free-radical cure may also be added to the compositions described herein to extend the useful shelf life. Examples of free-radical inhibitors include hindered phenols such as 2,6-di-tert-butyl4-methylphenol; 2,6-di-tert-butyl-4-methoxyphenol; tert-butyl hydroquinone; tetrakis(methylene (3,5-di-tert-butyl-4-hydroxyhydrocinnamate))benzene; 2,2′-methylenebis(6-tertbutyl-p-cresol); and 1,3,5-trimethyl-2,4,6-tris(3′,5′-di-tertbutyl-4-hydroxybenzyl)benzene. Other useful hydrogen donating antioxidants such as derivatives of p-phenylenediamine and diphenylamine. It is also well know in the art that hydrogen-donating antioxidants may be synergistically combined with quinones and metal deactivators to make a very efficient inhibitor package. Examples of suitable quinones include benzoquinone, 2-tert butyl-1,4-benzoquinone; 2-phenyl-1,4-benzoquinone; naphthoquinone, and 2,5-dichloro-1,4-benzoquinone. Examples of metal deactivators include N,N′-bis(3,5-di-tert-butyl-4-hydroxyhydrocinnamoyl)hydrazine; oxalyl bis(benzylidenehydrazide); and N-phenyl-N′-(4-toluenesulfonyl)-p-phenylenediamine amine.

Nitroxyl radical compounds such as TEMPO (2,2,6,6-tetramethyl-1-piperidnyloxy, free radical) are also effective as inhibitors at low concentrations. The total amount of antioxidant plus synergists typically falls in the range of 100 to 2000 ppm relative to the weight of total base resin. Other additives, such as adhesion promoters, in types and amounts known in the art, may also be added.

### Properties of Wafer Passivation Coatings Containing Low Modulus Polyimides

Advantageously, the low modulus, functionalized polyimide compounds of the invention can impart many properties that are desirable in a passivation coating. Historically, polyimide coatings for water passivation have been based on high T_{g} resins that are either formed in situ on the wafer surface via cyclodehydration of their amic acid precursors, or if preimidized are only soluble in high boiling, expensive solvents such as N-methyl-2-pyrrolidone (NMP) which is difficult to remove form the final film. The passivation layer compositions of the invention containing low modulus, functionalized polyimide compounds that are fully imidized oligomers and can be spin coated onto the wafer either neat or dissolved in a variety of low cost, readily available solvents. The compounds of this invention are intrinsically hydrophobic and have significantly lower moisture absorption when fully cured than the traditional polyimide coatings, which can absorb as much as 4-5% moisture by weight. Furthermore, the compounds of this invention provide low modulus coatings after cure and thus are much better suited for use on thinned silicon devices.

The polyimide resins of this invention cure to low modulus films. The modulus of these films, post cure, is less than about 2,000 MPa at 25° C., such as less than about 1,000 MPa at 25° C., for example, less than about 100 MPa at 25° C., e.g., less than about 25 MPa at 25° C.

The invention will now be further described with reference to by the following illustrative, non-limiting examples.

### EXAMPLES

### Example 1

A 500-mL round-bottomed flask equipped with Teflon® (DuPont) coated stir bar was charged with 32.7 g (0.15 mol) of pyromellitic dianhydride, 150 mL of NMP and 100 mL of toluene. The mixture was stirred at room temperature and slowly 54.0 g (0.10 mol) of dimer diamine (VERSAMINE® 552, BASF Corporation) was added to the flask. The thick mixture was heated to reflux and the water generated in the reaction was azeotropically removed using a Dean-Stark trap. After overnight reflux at a temperature of about 115° C. 3.6 mL of water was collected. The anhydride-capped polyimide solution was cooled down to about 50° C., followed by the addition of 14.5 g (0.125 mol) of hydroxyethyl acrylate, 500 ppm of butylated hydroxytoluene (BHT) and 0.12 g of N,N-dimethyl aminopyridine to catalyze the reaction. The solution was allowed to stir overnight at 60° C. to complete the reaction. The product was purified and isolated by precipitation in stirring methanol. Approximately 75 g of a white amorphous solid was obtained after several additional rinses with methanol, and drying the material.

### Example 2

### TMAH as the Image Development Solvent

The acrylate-functionalized polyimide of example 1 was dissolved in cyclohexanone to make a 40% solution, also 1 wt % IRGACURE® 819 (bis(2,4,6-trimethylbenzoyl)-phenylphosphineoxide; Ciba Specialty Chemicals, Basel) along with 2 wt % IRGACURE® 651 (2,2-Dimethoxy-1,2-diphenylethan-1-one; Ciba Specialty Chemicals, Basel) were dissolved in the cyclohexanone solution. To the solution was also added 500 ppm of butylated hydroxytoluene (BHT) and 1 wt % aminoproplytrimethoxysilane. The solution was filtered through filter paper to get rid of any debris. The solution was then spin-coated onto a silicon wafer, and allowed to dry in an oven at 70° C. for 15 minutes (surface was non-tacky). A photomask was placed on top of the silicon wafer, and exposed to UV light for approximately 45 seconds. The technique used for developing the photoresist was by flooding with 2.5% tetramethylammonium hydroxide (TMAH) solution. The image began to appear about 5 minutes after soaking, and was never completely developed even after soaking for one hour.

### Example 3

A 1 L reaction flask was charged with 300 mmol (65.4 g) of pyromellitic dianhydride. To the solid was added 300 g of toluene and 300 g of N-methyl-2-pyrrolidone (NMP). The material was stirred to completely dissolve the solid. A dropping funnel was charged with 170 mmol (91.1 g) of Versamine-552 dissolved in 100 g of toluene. The solution was added to the stirred dianhydride to form the polyamic acid. The solution was heated to reflux for 16 hours to complete the polyimide formation. After cooling down to 50° C., hydroxyethyl acrylate (325 mmol, 37.7 g) was added to the solution, along with 500 ppm of BHT and 0.1 g of 4-dimethylaminopyridine (DMAP). The solution was stirred for about 10 hours at 50° C. to make sure the reaction was complete. The cooled solution was added drop-wise to methanol to precipitate the oligomer. After filtering and drying, approximately 120 g of a slightly yellow powder was collected.

### Example 4

The polyimide produced in example 3 was dissolved in cyclohexanone to make a 40 wt % solution. IRGACURE® 819 (1 wt %) (Bis(2,4,6-trimethylbenzoyl)-phenylphosphineoxide; Ciba Specialty Chemicals, Basel), IRGACURE® 651 (2 wt %) (2,2-Dimethoxy-1,2-diphenylethan-1-one; Ciba Specialty Chemicals, Basel), aminopropyl trimethoxysilane (1 wt %), and 500 ppm BHT were also dissolved in the cyclohexanone solution. The solution was filtered through filter paper to eliminate any debris, followed by spin coating onto a silicon wafer. The silicon wafer was placed in an oven at 70° C. for 15 minutes to dry completely to produce a non-tacky surface. A photomask was placed on the wafer and exposed to UV light for 45 seconds. The wafer was flood-coated by placing in a 2.5 wt % solution of TMAH. This lower molecular weight material started to develop in approximately 30 seconds, and was fully developed in about 5 minutes. The wafer was then rinsed with deionzed water and dried in the oven for 10 minutes at 70° C. The imaged and developed pattern was characterized using a contact profilometer. In all cases, the replication of mask dimensions in the imaged pattern was excellent with very good edge definition. This demonstrated that compositions of the invention were suited for use as photoimagable, negative tone, and aqueous developable passivation layers.

### Example 5

The polyimide oligomer synthesized in EXAMPLE 3 was dissolved in toluene (80 wt % solution); 1 wt % IRGACURE® 819 (bis(2,4,6-trimethylbenzoyl)-phenylphosphineoxide; Ciba Specialty Chemicals, Basel), 1 wt % IRGACURE® 651 (2,2-Dimethoxy-1,2-diphenylethan-1-one; Ciba Specialty Chemicals, Basel) and 500 ppm of BHT were added and dissolved. The material was poured into a dogbone-shaped aluminum mold, and placed in a vacuum oven at 70° C. for 1 hour to remove the solvent and degas the resin. The mold was exposed to UV light for several minutes to cure the sample. The tensile strength of the sample was measured at 1260 psi using an INSTRON® tensile tester (Instron®, Norwood, Mass.) with approximately 40% elongation.

### Example 6

The material synthesized in EXAMPLE 3 was again cast from toluene into small molds and UV cured for several minutes. The samples were tested for elastic modulus using a Dynamic Mechanical Analyzer (DMA). The room temperature elastic modulus (Young's modulus) of the material was measured at about 245 MPa.

### Example 7

The material synthesized in EXAMPLE 3 was again cast from toluene into small molds and UV cured for several minutes. The cured samples were placed in an 85/85 chamber (85° C., 85% relative humidity) for 160 hours, and were found to have less than 5% moisture uptake.

### Example 8

The material synthesized in EXAMPLE 3 was again cast from toluene into small molds and UV cured for several minutes. A small piece approximately 50 mg was placed in a TGA (Thermogravimetric Analyzer) pan and heated to 350° C. at a ramp rate of 10° C. per minute. The sample was found to have less than 4% weight loss at 300° C., and most of this was due to incomplete removal of the toluene.

### Example 9

A 1 L reactor was charged with 400 mmol (87.2 g) of pyrromelitic dianhydride. To the reactor was also added 300 g of toluene and 300 g of N-methyl-2-pyrrolidone (NMP); stirring caused the solid to dissolve completely. To the reactor was added 100 mmol (15.2 g) of 3,5-diaminobenzoic acid, and the solution was heated to reflux for 5 hours to collect about 4 mL of water from the condensation reaction. A dropping funnel was charged with 200 mmol (107.2 g) of Versamine®552 along with 100 g of toluene. The solution was slowly added to the stirred solution while stirring vigorously. After the complete addition, the solution was again refluxed for approximately 16 hours to complete the condensation reaction and collect 7.2 mL of water. The solution was cooled down to about 50° C., and 300 mmol (34.8 g) of hydroxyethyl acrylate was added along with 500 ppm of BHT and 0.1 g of DMAP. The solution was stirred for 6 hours at 50° C. to complete the reaction. After cooling to room temperature the solution was poured into stirred bucket of methanol to precipitate the product. The dark brown solid (approximately 180 g) was collected after filtering and drying.

### Example 10

A 1 L reactor was charged with 200 mmol (107.2 g) of Versamine® 552 and dissolved in 300 g of toluene and 300 g of N-methyl-2-pyrrolidone (NMP). To the reactor was added 125 mmol (27.3 g) of pyrromelitic dianhydride with vigorous stirring to form the amine-terminated polyamic acid. The solution was refluxed for 6 hours to form the amine-terminated polyimide. The solution was cooled to room temperature, followed by the addition of 180 mmol (17.6 g) of maleic anhydride. The solution was stirred at 50° C. for 2 hours to assure the complete reaction of the maleic anhydride. Once cooled the solution is poured into stirred methanol in a bucket. After filtering and drying, approximately 90 g of a yellow slightly tacky solid was collected.

What is claimed is:

1. A functionalized polyimide, comprising at least one compound selected from the group consisting of compounds of formulae I-VII: 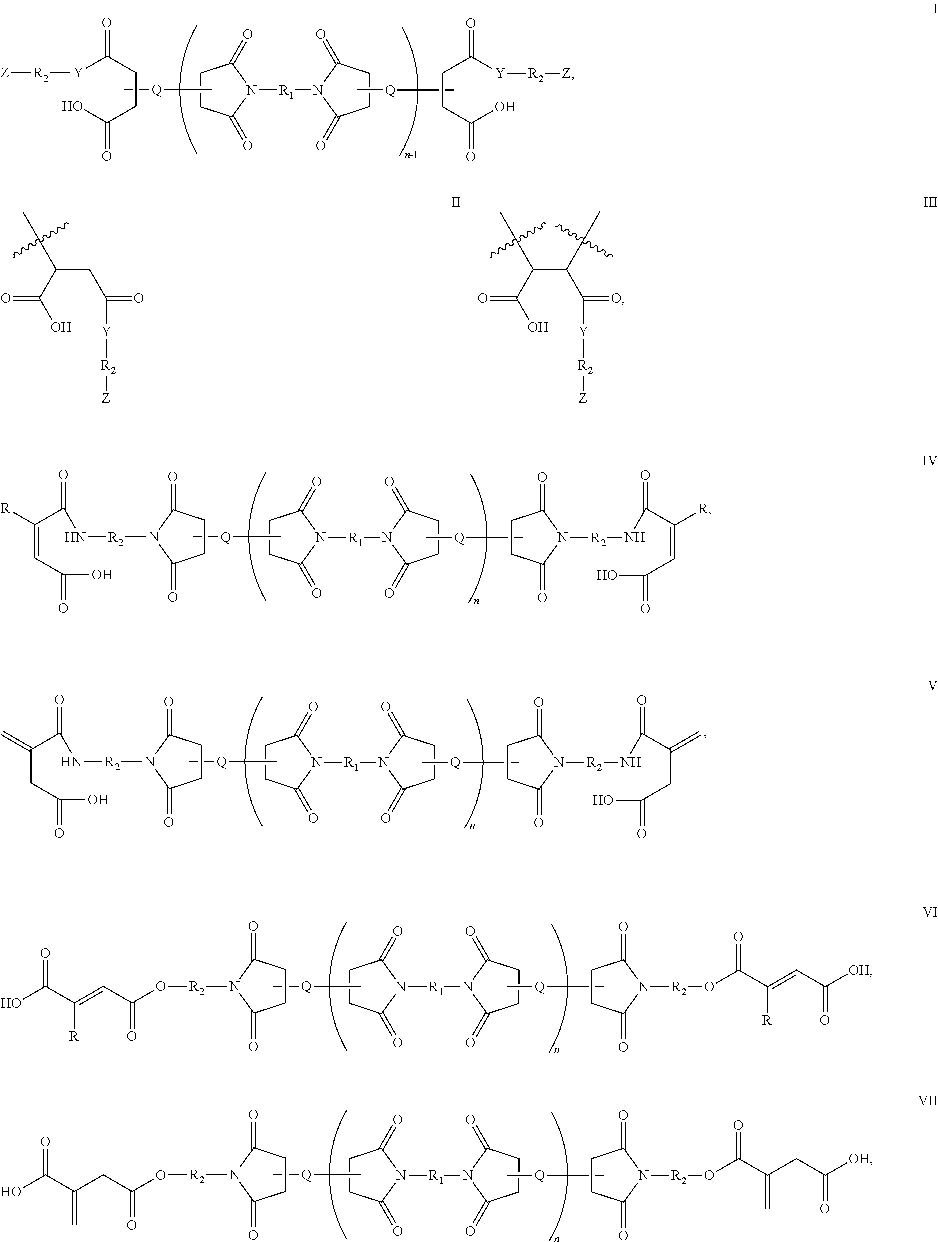
wherein, each R₁, R₂, and Q is independently selected from the group consisting of substituted or unsubstituted aliphatic, substituted or unsubstituted alkenyl, substituted or unsubstituted aromatic, substituted or unsubstituted heteroaromatic and siloxane moieties;
Y in each structure is a heteroatom;
Z in each structure is a polymerizable moiety; and
n in each structure is an integer having the value between 1 to about 10; and
the symbol “ [symbol] ” depicts schematically a macromolecular chain to which the structure II or III is covalently attached.

2. The functionalized polyimide of claim 1, wherein each R₁, R₂ and Q is independently selected from a group consisting of:
a substituted or an unsubstituted linear, branched, cyclic, aliphatic and alkenyl moieties having between 2 and 500 carbon atoms; and
a substituted or unsubstituted aromatic or heteroaromatic moieties having between 6 and 20 carbon atoms.

3. The functionalized polyimide of claim 1, wherein at least one R₁ or R₂ is a 36-carbon atom moiety.

4. The functionalized polyimide of claim 3, is compound selected from the group consisting of:

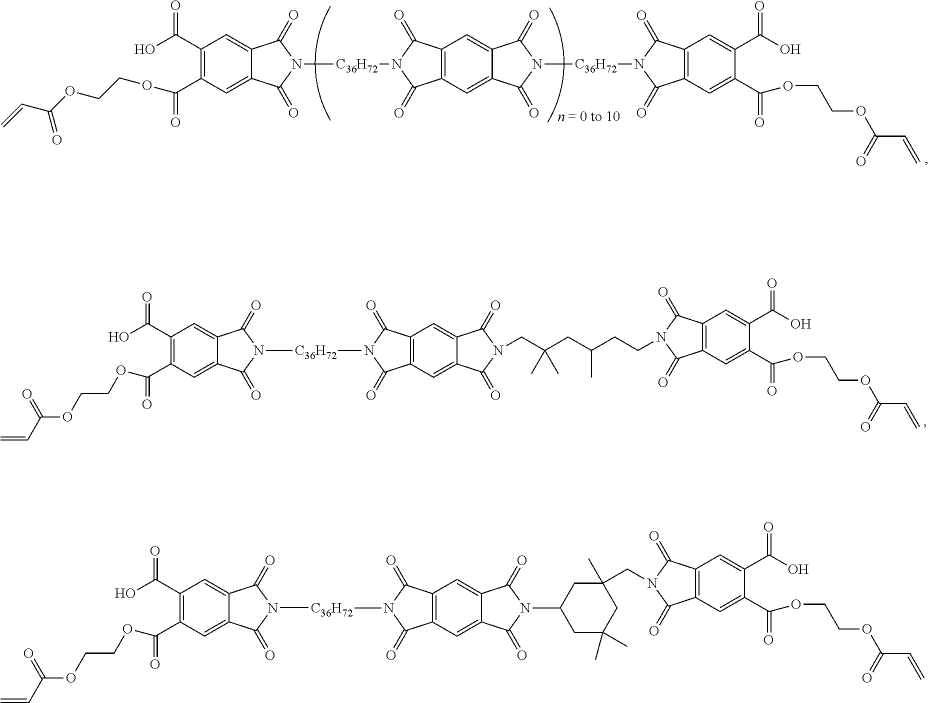

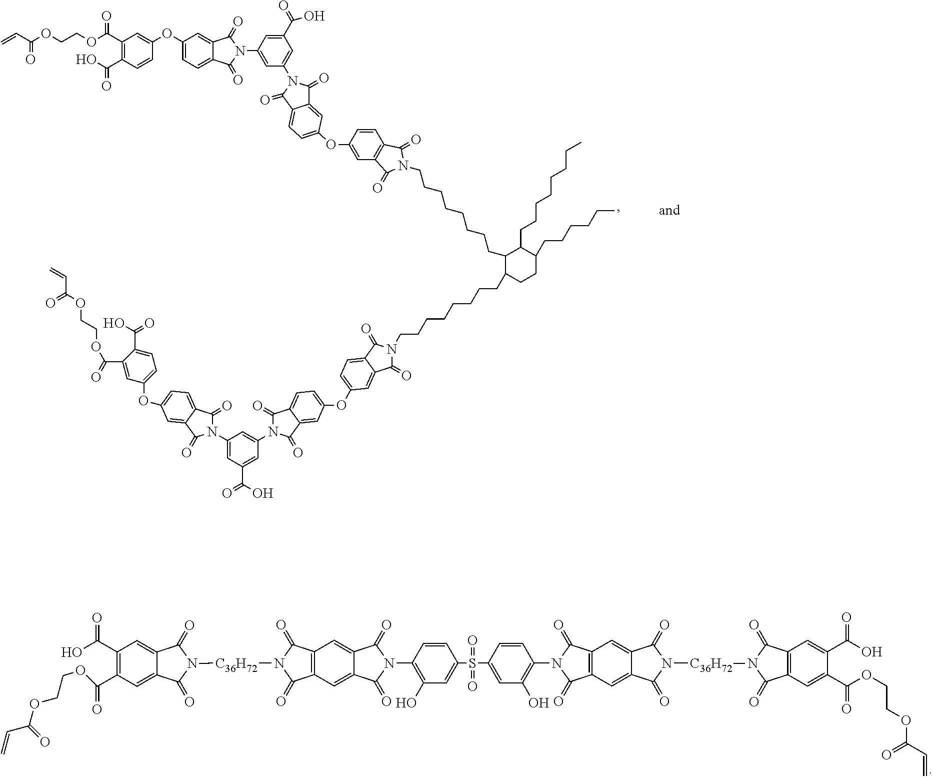

5. The functionalized polyimide of claim 1, wherein R₁ is an aromatic moiety having any one of the following structures: 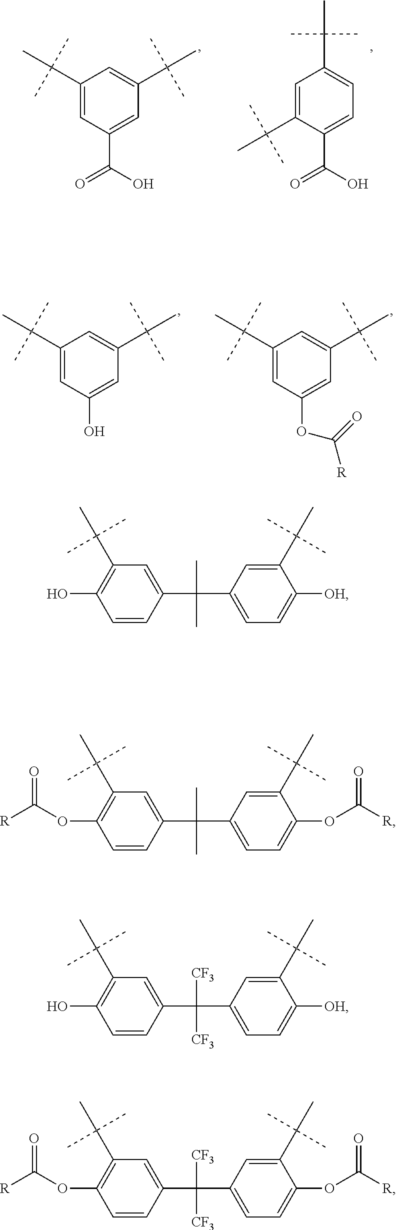 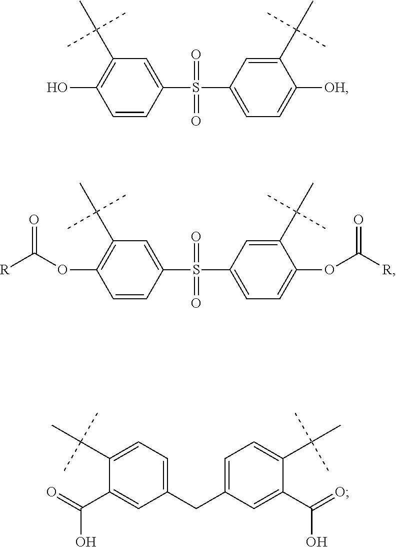
wherein R is an aliphatic or aromatic substituent.

6. The functionalized polyimide of claim 1, wherein the acid equivalent weight is between 300 and 2000 g per equivalent.

7. The functionalized polyimide of claim 1, wherein the polymerizable moiety is selected from the group consisting of a cationic polymerizable moiety, an anionic polymerizable moiety, a ring-opening polymerizable moiety, and a free-radical polymerizable moiety.

8. The functionalized polyimide of claim 1, wherein the polymerizable moiety is selected from the group consisting of an acrylate, a methacrylate, a vinyl ether, a vinyl ester, an epoxy, an oxetane, a maleimides, a citraconimide, a itaconates, or a maleate.

9. The functionalized polyimide of claim 1, wherein the compound has the structure:

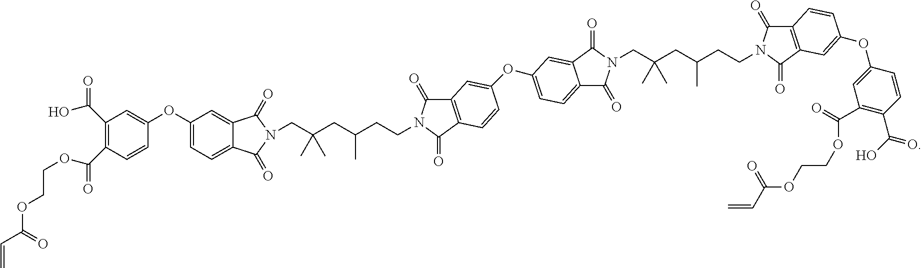 [SMILES: C=CC(=O)OCCOC(=O)c1ccc(Oc2ccc3c(c2)C(=O)N(CC(C)(C)CC(C)CCN2C(=O)c4ccc(Oc5ccc6c(c5)C(=O)N(CC(C)(C)CC(C)CCN5C(=O)c7ccc(Oc8ccc(C(=O)O)c(C(=O)OCCOC(=O)C=C)c8)cc7C5=O)C6=O)cc4C2=O)C3=O)cc1C(=O)O]

10. A device, comprising:
a semiconductor wafer, wafer level package, MEMS, PTC protective layer, circuit board, or glass; and
a passivation layer disposed on the surface of the wafer, wherein the passivation layer comprises a functionalized polyimide compound selected from the group consisting of compounds of formulae I-VII: 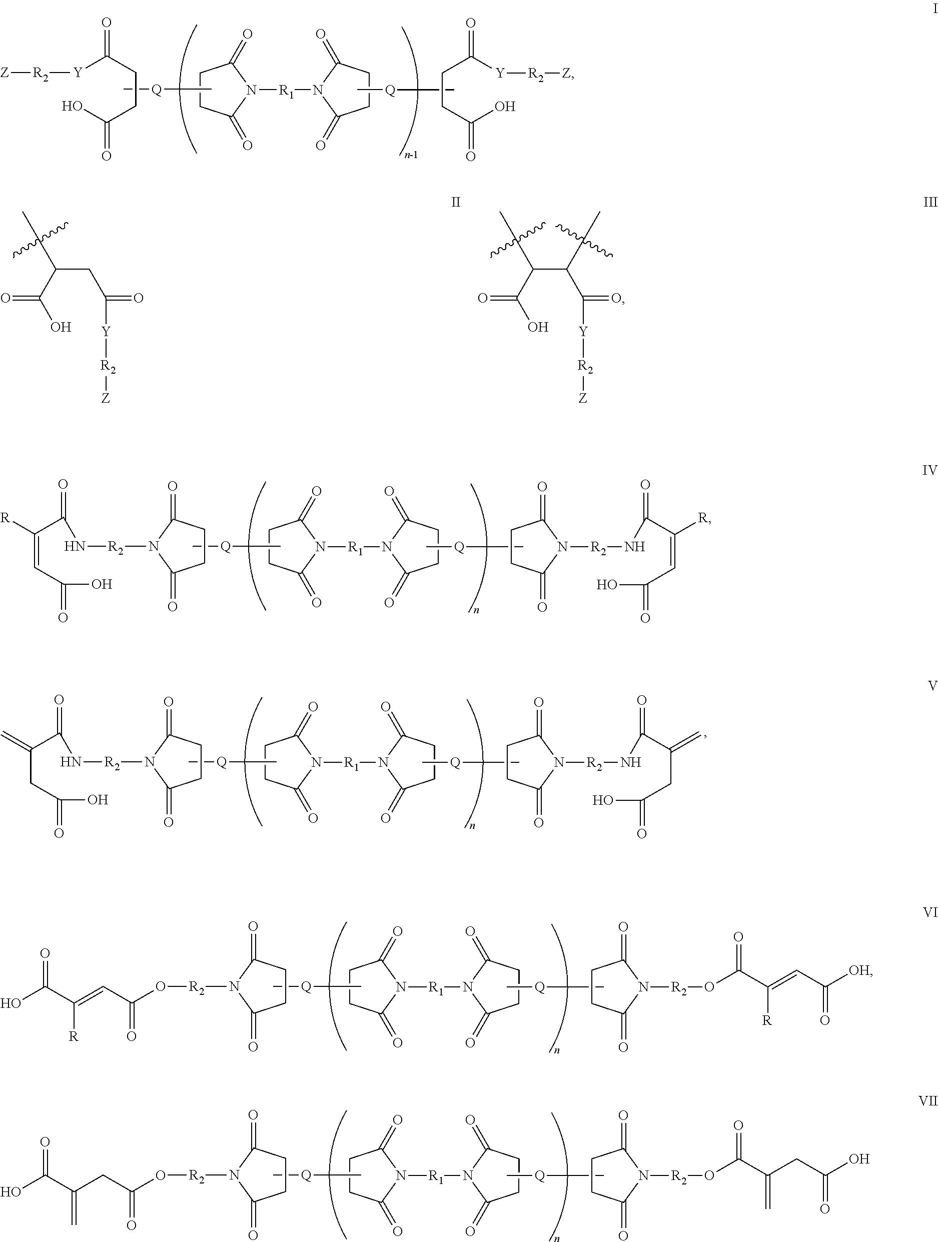
where, each R₁, R₂, and Q is independently selected from the group consisting of substituted or unsubstituted aliphatic, alkenyl, aromatic, heteroaromatic and siloxane moieties,
Y is a heteroatom such as oxygen, sulfur or nitrogen,
Z is a polymerizable moiety, n is an integer having the value between 1 to about 10, and
the symbol “ [symbol] ” depicts schematically a macromolecular chain to which the structure II or III is covalently attached.

11. The device of claim 10, wherein the polyimide coating form a film after cure that has a modulus of less than 2000 MPa at 25° C.

12. The device of claim 11, wherein the modulus is less than 1000 MPa at 25° C.

13. The device of claim 12, wherein the modulus is less than 500 MPa at 25° C.

14. A method of fabricating the device of claim 10, comprising:
depositing a layer of the functionalized polyimide on the surface of the semiconductor wafer; and
curing the functionalized polyimide to thereby form a polyimide passivation layer on the surface of the semiconductor wafer; and
developing the uncured functionalized polyimide using an aqueous developing solution, thereby forming a pattern on the surface of the semiconductor wafer.

15. The method of claim 14, wherein a concentrated solution is made comprising:
the functionalized polyimide, UV initiators, coupling agents, inhibitors, adhesion promoters, and solvent; and
spin coating the solution onto a semiconductor wafer.
